(19) United States
(12) Patent Application Publication
(10) Pub. No.: US 2022/0199580 A1
(43) Pub. Date: Jun. 23, 2022

(54) SEMICONDUCTOR DEVICE AND MANUFACTURING METHOD THEREOF

(71) Applicant: Kioxia Corporation, Tokyo (JP)

(72) Inventors: Soichi HOMMA, Yokkaichi Mie (JP); Daisuke SAKAGUCHI, Mie Mie (JP)

(73) Assignee: Kioxia Corporation, Tokyo (JP)

(21) Appl. No.: 17/412,554

(22) Filed: Aug. 26, 2021

(30) Foreign Application Priority Data
Dec. 21, 2020 (JP) 2020-211473

(51) Int. Cl. H01L 25/065; H01L 25/10; H01L 23/31; H01L 23/498

(52) U.S. Cl. CPC H01L 25/0657; H01L 25/105; H01L 23/3128; H01L 2225/06548; H01L 23/49816; H01L 2225/06562; H01L 23/49822

(57) ABSTRACT

A semiconductor device according to the present embodiment includes a plurality of stacked first semiconductor chips. First columnar electrodes are connected to electrode pads of the first semiconductor chips and extend in a stacking direction of the first semiconductor chips. A plurality of second semiconductor chips are stacked above the first semiconductor chips. Second columnar electrodes are connected to electrode pads of the second semiconductor chips and extend in a stacking direction of the second semiconductor chips. Third columnar electrodes are respectively connected to tops of the first columnar electrodes and extend in the stacking direction of the second semiconductor chips. A resin layer covers the first semiconductor chips, the second semiconductor chips, the second columnar electrodes, and the third columnar electrodes and exposes tops of the second and third columnar electrodes.

### CROSS REFERENCE TO RELATED APPLICATIONS

This application is based upon and claims the benefit of priority from the prior Japanese Patent Application No. 2020-211473, filed on Dec. 21, 2020, the entire contents of which are incorporated herein by reference.

### FIELD

The embodiments of the present invention relate to a semiconductor device and a manufacturing method thereof.

### BACKGROUND

In a semiconductor package formed by resin sealing of a plurality of semiconductor chips, columnar electrodes made of metallic wires are provided on an electrode pad of each of the semiconductor chips in some cases. The metallic wires are connected to the electrode pads of the semiconductor chips by a wire bonding method and are drawn in a vertical direction to be formed in the vertical direction.

However, in a case in which many semiconductor chips are stacked, metallic wires connected to a lowermost semiconductor chip need to be drawn to be long in the vertical direction. When the metallic wires are made long, the locations of the tops of the metallic wires are sometimes greatly displaced or the metallic wires may even fall at the time of resin sealing. When the pitch between the electrode pads is narrow in this case, there is a risk that adjacent ones of the columnar electrodes interfere with each other.

### BRIEF DESCRIPTION OF THE DRAWINGS

FIG. 1A is a sectional view illustrating an example of a configuration of a semiconductor device according to a first embodiment;

FIG. 1B is a sectional view illustrating an example of the configuration of the semiconductor device according to the first embodiment;

FIG. 2A is a sectional view illustrating a configuration example of the semiconductor device further including a redistribution layer and metallic bumps in addition to the configuration illustrated in FIG. 1A;

FIG. 2B is a sectional view illustrating a configuration example of the semiconductor device further including a redistribution layer and metallic bumps in addition to the configuration illustrated in FIG. 1B;

FIGS. 3 to 11 are sectional views illustrating an example of the manufacturing method of the semiconductor device according to the first embodiment;

FIG. 12 is a sectional view illustrating an example of a configuration of a semiconductor device according to a second embodiment;

FIGS. 13 to 20 are sectional views illustrating an example of the manufacturing method of the semiconductor device according to the second embodiment;

FIG. 21 is a sectional view illustrating a configuration example of a semiconductor device according to a third embodiment;

FIG. 22 is a schematic sectional view illustrating a configuration example of columnar electrodes and connection parts;

FIG. 23 is a sectional view illustrating a configuration example of a semiconductor device according to a fourth embodiment;

FIG. 24 is a sectional view illustrating a configuration example of a semiconductor device according to a fifth embodiment;

FIG. 25 is a sectional view illustrating a configuration example of a semiconductor device according to a sixth embodiment;

FIG. 26 is a sectional view illustrating a configuration example of a semiconductor device according to a seventh embodiment;

FIG. 27 is a schematic sectional view illustrating a configuration example of additional pads, connection parts, and a periphery thereof;

FIG. 28 is a sectional view illustrating a configuration example of a semiconductor device according to an eighth embodiment;

FIGS. 29 to 31 are sectional views respectively illustrating configuration examples of the semiconductor device according to a ninth embodiment;

FIG. 32 is a sectional view illustrating a configuration example of a semiconductor device according to a tenth embodiment;

FIG. 33 is a sectional view illustrating a configuration example of the semiconductor device according to the tenth embodiment;

FIGS. 34 to 39 are sectional views respectively illustrating configuration examples of the semiconductor device 1 according to an eleventh embodiment;

FIG. 40A is a sectional view illustrating a configuration example of a semiconductor device according to a twelfth embodiment;

FIG. 40B is a sectional view illustrating a configuration example of the semiconductor device according to the twelfth embodiment;

FIG. 41 is a sectional view illustrating a configuration example of a semiconductor device according to a thirteenth embodiment;

FIG. 42 is a sectional view illustrating a configuration example of a semiconductor device according to a fourteenth embodiment;

FIG. 43 is a sectional view illustrating a configuration example of the semiconductor device according to the fourteenth embodiment;

FIG. 44 is a sectional view illustrating a configuration example of a semiconductor device according to a fifteenth embodiment; and

FIG. 45 is a sectional view illustrating a configuration example of a semiconductor device according to a sixteenth embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a stacking direction of semiconductor chips is assumed as “an upper or a lower direction”. Therefore, the term “upper direction” or “lower direction” occasionally differs from an upper direction or a lower direction based on a gravitational acceleration direction. In the present specification and the drawings, elements identical to those described in the foregoing drawings are denoted by like reference characters and detailed explanations thereof are omitted as appropriate.

A semiconductor device according to the present embodiment includes a plurality of stacked first semiconductor chips. First columnar electrodes are connected to electrode pads of the first semiconductor chips and extend in a stacking direction of the first semiconductor chips. A plurality of second semiconductor chips are stacked above the first semiconductor chips. Second columnar electrodes are connected to electrode pads of the second semiconductor chips and extend in a stacking direction of the second semiconductor chips. Third columnar electrodes are respectively connected to tops of the first columnar electrodes and extend in the stacking direction of the second semiconductor chips. A resin layer covers the first semiconductor chips, the second semiconductor chips, the second columnar electrodes, and the third columnar electrodes and exposes tops of the second and third columnar electrodes.

### First Embodiment

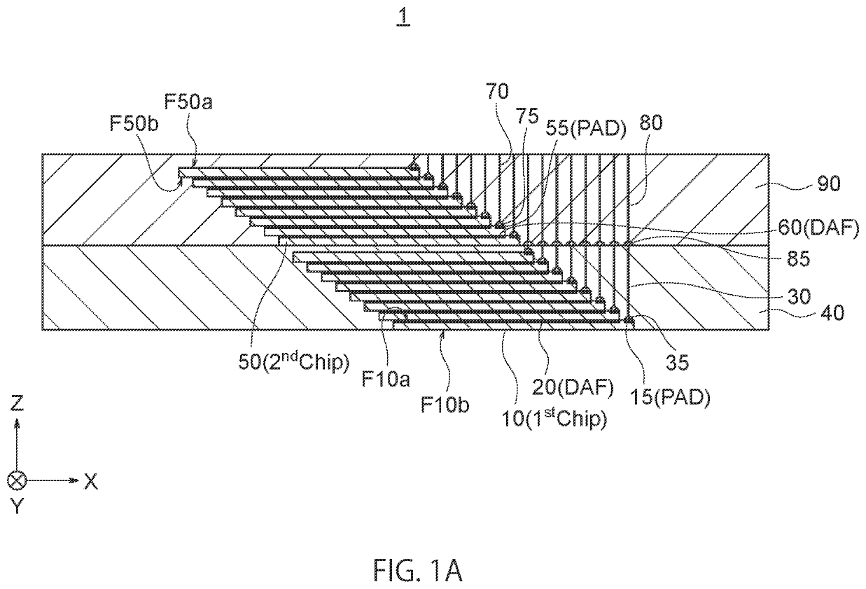

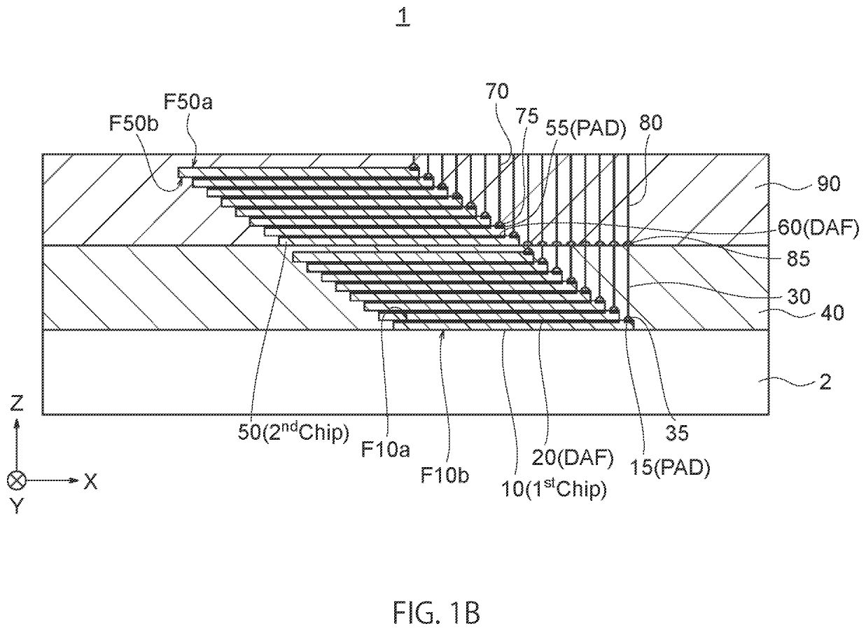

FIGS. 1A and 1B are sectional views respectively illustrating examples of a configuration of a semiconductor device 1 according to a first embodiment. The semiconductor device 1 includes semiconductor chips 10, adhesive layers (DAFs (Die Attachment Films)) 20, columnar electrodes 30, a resin layer 40, semiconductor chips 50, adhesive layers (DAFs) 60, columnar electrodes 70, columnar electrodes 80, and a resin layer 90. The semiconductor device 1 can be a semiconductor package such as a NAND flash memory or an LSI (Large Scale Integration).

Each of the semiconductor chips 10 has a first face F10a and a second face F10b on the opposite side to the first face F10a. Semiconductor elements (not illustrated) such as a transistor and a capacitor are formed on the first faces F10a of the semiconductor chips 10. The semiconductor elements on each of the first faces F10a of the semiconductor chips 10 are covered and protected by an insulating film (not illustrated). For example, an inorganic insulating material such as a silicon dioxide film or a silicon nitride film is used as the insulating film. A material including an organic insulating material formed on an inorganic insulating material may be used as the insulating film. For example, an organic insulating material such as a phenol-based resin, a polyimide-based resin, a polyamide-based resin, an acrylic-based resin, an epoxy-based resin, a PBO (p-phenylene benzobisoxazole)-based resin, a silicon-based resin, or a benzocyclobutene-based resin, or a mixed material or a composite material thereof is used as the organic insulating material. The semiconductor chips 10 can be, for example, memory chips of a NAND flash memory or semiconductor chips having any LSI mounted thereon. While the semiconductor chips 10 can be semiconductor chips having a same configuration, the semiconductor chips 10 may be semiconductor chips having configurations different from each other.

The semiconductor chips 10 are stacked and are stuck with the adhesive layers 20, respectively. For example, an organic insulating material such as a phenol-based resin, a polyimide-based resin, a polyamide-based resin, an acrylic-based resin, an epoxy-based resin, a PBO-based resin, a silicon-based resin, or a benzocyclobutene-based resin, or a mixed material or a composite material thereof is used as the adhesive layers 20. Each of the semiconductor chips 10 has an electrode pad 15 exposed on the first face F10a. Another semiconductor chip 10 (an upper-tier semiconductor chip 10) stacked on a semiconductor chip 10 (a lower-tier semiconductor chip 10) is stacked to be displaced in a substantially perpendicular direction (an X direction) with respect to a side on which the electrode pad 15 of the lower-tier semiconductor chip 10 is provided, so as not to overlap with the electrode pad 15 of the lower-tier semiconductor chip 10.

Each of the electrode pads 15 is electrically connected to any of the semiconductor elements provided on the corresponding semiconductor chip 10. For example, a low-resistance metal such as a simple substance of Cu, Ni, W, Au, Ag, Pd, Sn, Bi, Zn, Cr, Al, Ti, Ta, TiN, TaN, CrN, or the like, a composite membrane including two or more thereof, or an alloy including two or more thereof is used as the electrode pads 15.

The columnar electrodes 30 are connected to the electrode pads 15 of the semiconductor chips 10 and extend in a stacking direction (a Z direction) of the semiconductor chips 10. The adhesive layers 20 are partially removed to expose portions of the electrode pads 15 and enable the columnar electrodes 30 to be connected to the electrode pads 15. Alternatively, each of the adhesive layers 20 is stuck to the second face F10b of the associated upper-tier semiconductor chip 10 and is provided so as not to overlap with the electrode pad 15 of the associated lower-tier semiconductor chip 10. The lower ends of the columnar electrodes 30 are connected to the electrode pads 15 by a wire bonding method and connection parts 35 thereof have a ball shape larger than the diameter (the thickness) in the X direction or a Y direction of the columnar electrodes 30. The upper ends of the columnar electrodes 30 reach the upper surface of the resin layer 40 and are exposed on the upper surface.

The resin layer 40 covers (seals) the semiconductor chips 10 and the columnar electrodes 30 and exposes tops of the columnar electrodes 30 on the upper surface.

Each of the semiconductor chips 50 has a first face F50a and a second face F50b on the opposite side to the first face F50a. Semiconductor elements (not illustrated) such as a memory cell array, a transistor, and a capacitor are formed on the first faces F50a of the semiconductor chips 50. The semiconductor elements on each of the first faces F50a of the semiconductor chips 50 are covered and protected by an insulating film (not illustrated). For example, an inorganic insulating material such as a silicon dioxide film or a silicon nitride film is used as the insulating film. A material including an organic insulating material formed on an inorganic insulating material may be used as the insulating film. For example, an organic insulating material such as a phenol-based resin, a polyimide-based resin, a polyamide-based resin, an acrylic-based resin, an epoxy-based resin, a PBO-based resin, a silicon-based resin, or a benzocyclobutene-based resin, or a mixed material or a composite material thereof is used as the organic insulating material. The semiconductor chips 50 can be, for example, memory chips of a NAND flash memory or semiconductor chips having any LSI mounted thereon. While the semiconductor chips 50 can be semiconductor chips having a same configuration, the semiconductor chips 50 may be semiconductor chips having configurations different from each other. While the semiconductor chips 50 can be semiconductor chips having the same configuration as that of the semiconductor chips 10, the semiconductor chips 50 may be semiconductor chips having a different configuration from that of the semiconductor chips 10.

The semiconductor chips 50 are stacked and are stuck with the adhesive layers 60, respectively. Each of the semiconductor chips 50 has an electrode pad 55 exposed on the first face F50a. A semiconductor chip 50 stacked on another semiconductor chip 50 is stacked to be displaced in a substantially perpendicular direction (the X direction) with respect to a side on which the electrode pad 55 of the another semiconductor chip 50 is provided, so as not to overlap with the electrode pad 55 of the another semiconductor chip 50. The lowermost semiconductor chip 50 is provided on the resin layer 40 and the resin layer 40 is interposed between the uppermost semiconductor chip 10 and the lowermost semiconductor chip 50.

Each of the electrode pads 55 is electrically connected to any of the semiconductor elements provided on the corresponding semiconductor chip 50. For example, a low-resistance metal such as a simple substance of Cu, Ni, W, Au, Ag, Pd, Sn, Bi, Zn, Cr, Al, Ti, Ta, TiN, TaN, CrN, or the like, a composite membrane including two or more thereof, or an alloy including two or more thereof is used as the electrode pads 55.

The columnar electrodes 70 are connected to the electrode pads 55 of the semiconductor chips 50 and extend in a stacking direction (the Z direction) of the semiconductor chips 50. The adhesive layers 60 are partially removed to expose portions of the electrode pads 55 and enable the columnar electrodes 70 to be connected to the electrode pads 55. Alternatively, each of the adhesive layers 60 is stuck to the second face F50b of the associated upper-tier semiconductor chip 50 and is provided so as not to overlap with the electrode pad 55 of the associated lower-step semiconductor chip 50. The lower ends of the columnar electrodes 70 are connected to the electrode pads 55 by the wire bonding method and connection parts 75 thereof have a ball shape larger than the diameter (the thickness) in the X or Y direction of the columnar electrodes 70. The upper ends of the columnar electrodes 70 reach the upper surface of the resin layer 90 and are exposed on the upper surface.

The columnar electrodes 80 are respectively connected to the tops of the columnar electrodes 30 exposed on the upper surface of the resin layer 40 and extend in the stacking direction (the Z direction) of the semiconductor chips 50. The lower ends of the columnar electrodes 80 are respectively connected to the upper ends of the columnar electrodes 30 by the wire bonding method and connection parts 85 thereof have a ball shape larger than the diameters (the thicknesses) in the X direction or the Y direction of the columnar electrodes 30 and 80. That is, the connection parts 85 between the columnar electrodes 30 and the columnar electrodes 80 are larger in a cross section in a perpendicular direction (the X or Y direction) to the extending direction of the columnar electrodes 30 and 80 than the cross sections of the columnar electrodes 30 and 80.

The resin layer 90 covers (seals) the semiconductor chips 50 and the columnar electrodes 70 and 80 and exposes the tops of the columnar electrodes 70 and 80 on the upper surface.

For example, an organic insulating material such as a phenol-based resin, a polyimide-based resin, a polyamide-based resin, an acrylic-based resin, an epoxy-based resin, a PBO-based resin, a silicon-based resin, or a benzocyclobutene-based resin, or a mixed material or a composite material thereof is used as the resin layers 40 and 90.

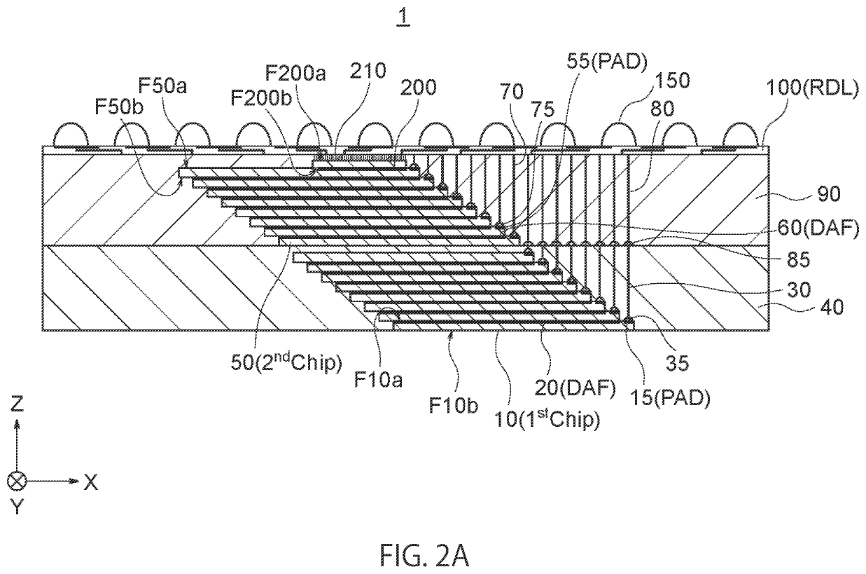

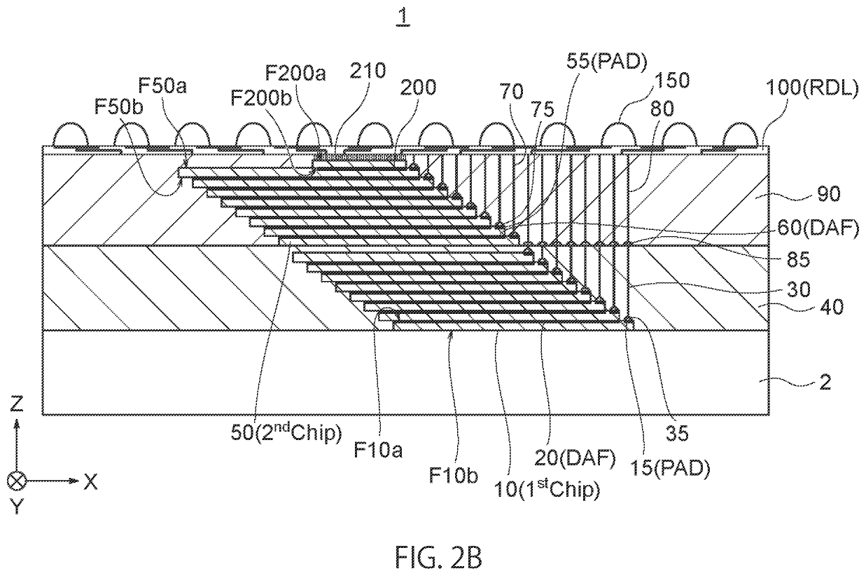

FIGS. 2A and 2B are sectional views illustrating configuration examples of the semiconductor device 1 further including semiconductor chips 200, columnar electrodes 210, a redistribution layer 100, and metallic bumps 150 in addition to the configurations illustrated in FIGS. 1A and 1B, respectively.

Each of the semiconductor chips 200 has a first face F200a and a second face F200b on the opposite side to the first face F200a. Semiconductor elements (not illustrated) such as a transistor and a capacitor are formed on each of the first faces F200a of the semiconductor chips 200. The semiconductor elements on each of the first faces F200a of the semiconductor chips 200 are covered and protected by an insulating film (not illustrated). For example, an inorganic insulating material such as a silicon dioxide film or a silicon nitride film is used as the insulating film. A material including an organic insulating material formed on an inorganic insulating material may be used as the insulating film. For example, an organic insulating material such as a phenol-based resin, a polyimide-based resin, a polyamide-based resin, an acrylic-based resin, an epoxy-based resin, a PBO-based resin, a silicon-based resin, or a benzocyclobutene-based resin, or a mixed material or a composite material thereof is used as the organic insulating material. The semiconductor chips 200 can be, for example, control chips that control memory chips (the semiconductor chips 10 and 50) or semiconductor chips having any LSI mounted thereon.

The semiconductor chips 200 are stacked on the semiconductor chips 50 and are stuck to the semiconductor chips 50 with the adhesive layers 60, respectively. Each of the semiconductor chips 200 has an electrode pad (not illustrated) exposed on the first face F200a.

The columnar electrodes 210 are connected to the electrode pad of each of the semiconductor chips 200 and extend in the Z direction. The adhesive layers 60 are partially removed to expose portions of the electrode pads and enable the columnar electrodes 210 to be connected to the associated electrode pads, respectively. Alternatively, the adhesive layers 60 are respectively stuck to the second faces F200b of the semiconductor chips 200 and are provided so as not to overlap with the electrode pads 55 of the lower-tier semiconductor chips 50. The lower ends of the columnar electrodes 210 are connected to the electrode pads of the semiconductor chips 200 by the wire bonding method and connection parts thereof have a ball shape larger than the diameter (the thickness) in the X direction of the columnar electrodes 210. The upper ends of the columnar electrodes 210 reach the upper surface of the resin layer 90 and are exposed on the upper surface. The same material as that of the columnar electrodes 30, 70, and 80 described above can be used for the columnar electrodes 210.

The redistribution layer (RDL) 100 is provided on the resin layer 90 and is electrically connected to the columnar electrodes 70, 80, and 210. The redistribution layer 100 is a multi-layer wiring layer including a plurality of wiring layers and a plurality insulating layers stacked and connects the columnar electrodes 70, 80, and 210 to the metallic bumps 150 in terms of electrodes, respectively.

The metallic bumps 150 are provided on the redistribution layer 100 and are electrically connected to the wiring layers of the redistribution layer 100. The metallic bumps 150 are used for connections to external devices (not illustrated). For example, a simple substance of Sn, Ag, Cu, Au, Pd, Bi, Zn, Ni, Sb, In, or Ge, or a composite membrane or an alloy of two or more thereof is used as the metallic bumps 150.

A manufacturing method of the semiconductor device 1 according to the first embodiment is explained next.

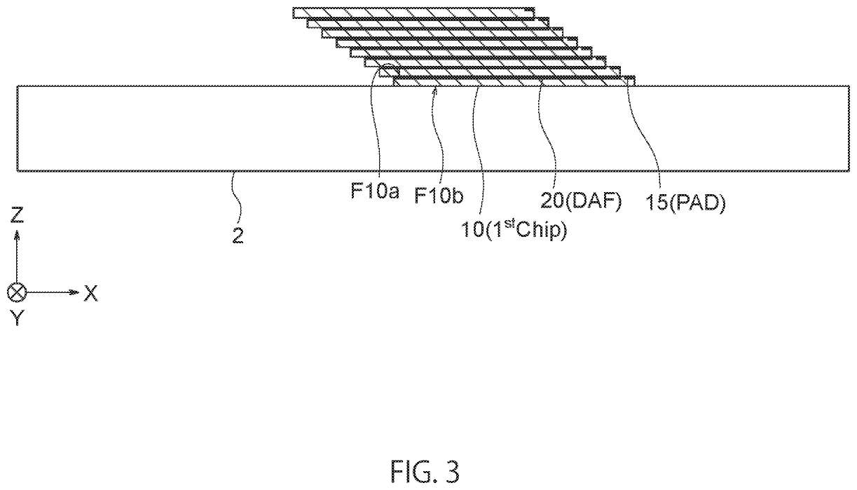

FIGS. 3 to 11 are sectional views illustrating an example of the manufacturing method of the semiconductor device 1 according to the first embodiment.

First, a plurality of semiconductor chips 10 are stacked on a support substrate 2 as illustrated in FIG. 3. At this time, each of the semiconductor chips 10 is stuck onto another semiconductor chip 10 with the adhesive layer 20. The support substrate 2 can be silicon, glass, ceramics, a resin plate, a metallic plate such as a lead frame, or the like.

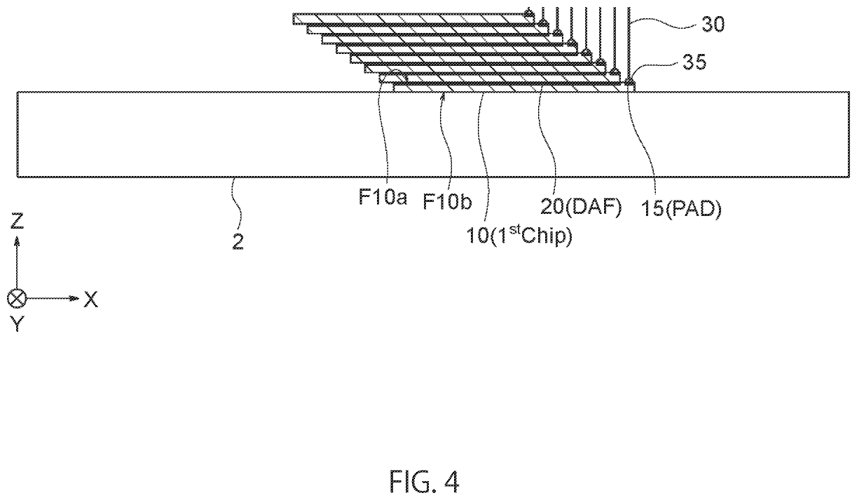

Next, metallic wires (conductive wires) are bonded onto the electrode pads 15 of the semiconductor chips 10 by the wire bonding method, and the metallic wires are drawn out in a substantially perpendicular direction to the first faces F10a to form the columnar electrodes 30 as illustrated in FIG. 4. Since the columnar electrodes 30 are formed by the wire bonding method, the lower ends of the columnar electrodes 30 are welded on the electrode pads 15 in a ball shape larger than the diameter (the thickness) in the X or Y direction of the columnar electrodes 30, respectively. Accordingly, the connection parts 35 larger than the diameter (the thickness) in the X or Y direction of the columnar electrodes 30 are formed between the electrode pads 15 and the columnar electrodes 30, respectively. As a result, the connection strength between the electrode pads 15 and the columnar electrodes 30 can be increased. The columnar electrodes 30 are cut at the upper ends and keep the upright states with stiffness of the columnar electrodes 30 themselves.

For example, a simple substance of Cu, Ni, W, Au, Ag, Pd, Sn, Bi, Zn, Cr, Al, Ti, or Ta, a composite material including two or more thereof, or an alloy including two or more thereof is used as the columnar electrodes 30. Preferably, a simple substance of Au, Ag, Cu, or Pd, a composite material including two or more thereof, an alloy including two or more thereof, or the like is used as the material of the columnar electrodes 30. More preferably, a material having a high hardness among these materials, for example, Cu, a CuPd alloy, or a material including Cu coated with Pd is used as the material of the columnar electrodes 30. Therefore, the columnar electrodes 30 are less likely to bend at the time of being covered with the resin layer 40 and are less likely to collapse.

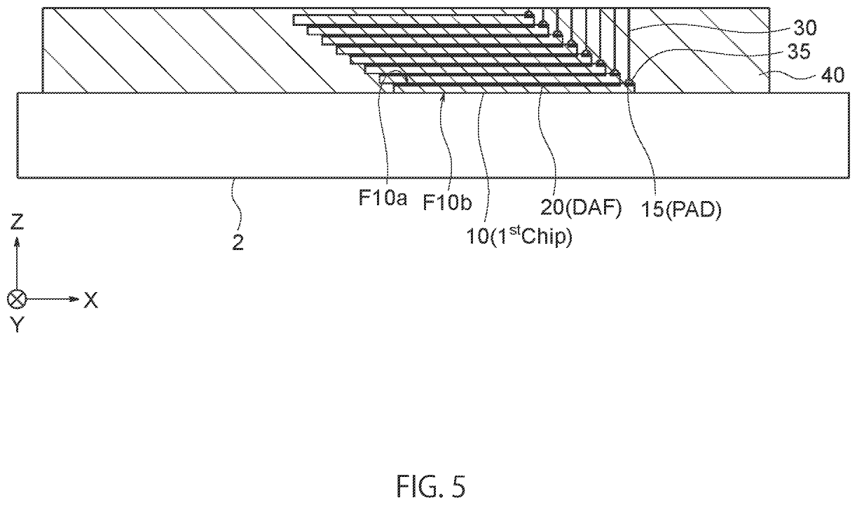

Next, the stacked body of the semiconductor chips 10 and the columnar electrodes 30 are covered with the resin layer 40 as illustrated in FIG. 5. For example, an organic insulating material such as an epoxy-based resin, a phenol-based resin, a polyimide-based resin, a polyamide-based resin, an acrylic-based resin, a PBO-based resin, a silicon-based resin, or a benzocyclobutene-based resin, or a mixed material or a composite material thereof is used as the resin layer 40. Examples of the epoxy resin are bisphenol-based epoxy resins such as a bisphenol A type, a bisphenol F type, a bisphenol AD type, and a bisphenol S type, novolak-based epoxy resins such as a phenol novolak type and a cresol novolak type, aromatic epoxy resins such as a resorcinol-based epoxy resin and trisphenol methane triglycidyl ether, a naphthalene-based epoxy resin, a fluoren-based epoxy resin, a dicyclopentadiene-based epoxy resin, a polyether-modified epoxy resin, a benzophenone-based epoxy resin, an aniline-based epoxy resin, an NBR-modified epoxy resin, a CTBN-modified epoxy resin, and hydrogenated substances thereof although not particularly limited thereto. Among these materials, the naphthalene-based epoxy resin and the dicyclopentadiene-based epoxy resin are preferable because of a high adhesiveness with Si. The benzophenone-based epoxy resin is also preferable because it is likely to rapidly harden. These epoxy resins can be used alone, or two or more types thereof may be used in combination. A filler such as silica may be included in the resin layer 40.

After formation of the resin layer 40, the resin layer 40 is heated by an oven or the like or the resin layer 40 is irradiated with ultraviolet rays to cure the resin layer 40.

Next, the resin layer 40 is polished using a CMP (Chemical Mechanical Polishing) method, a mechanical polishing method, or the like until the columnar electrodes 30 are exposed. The structure illustrated in FIG. 5 is thereby obtained.

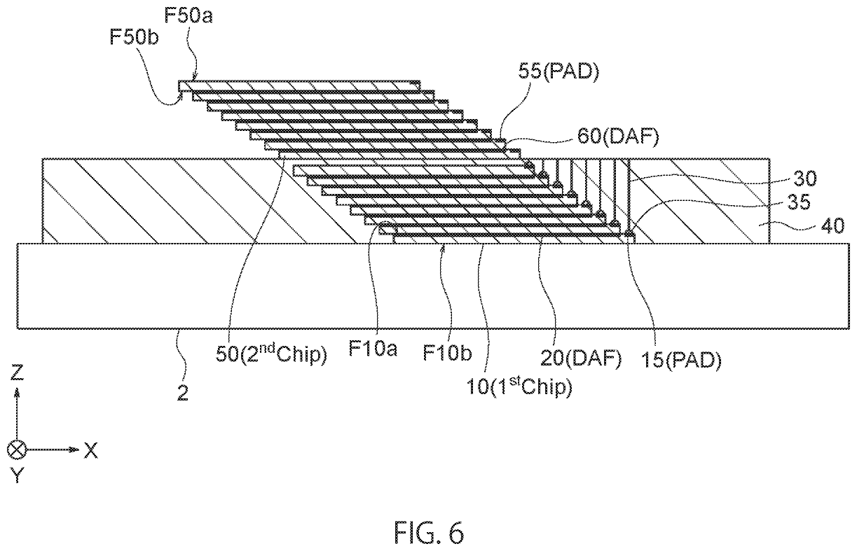

Next, a plurality of semiconductor chips 50 are stacked on the resin layer 40 as illustrated in FIG. 6. At this time, each of the semiconductor chips 50 is stuck onto another semiconductor chip 50 with the adhesive layer 60.

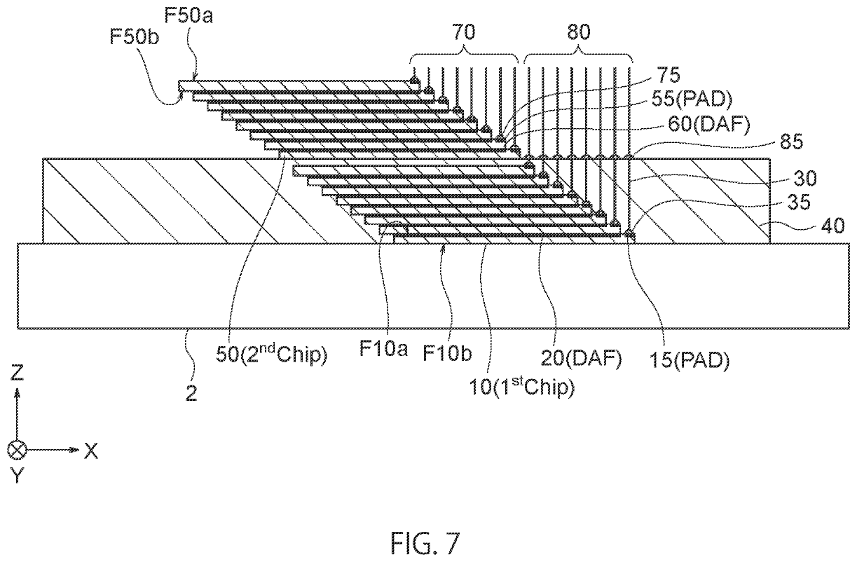

Subsequently, metallic wires are bonded onto the electrode pads 55 of the semiconductor chips 50 by the wire bonding method and the metallic wires are drawn out in a substantially perpendicular direction (the Z direction) to the first faces F50a to form the columnar electrodes 70 as illustrated in FIG. 7. Furthermore, metallic wires are bonded onto the upper ends of the columnar electrodes 30 exposed from the resin layer 40 by the wire bonding method and the metallic wires are drawn out in the Z direction to form the columnar electrodes 80, respectively. Since the columnar electrodes 70 and 80 are formed by the wire bonding method, the lower ends of the columnar electrodes 70 and 80 have a ball shape larger than the diameters (the thicknesses) in the X or Y direction of the columnar electrodes 70 and 80 on the electrode pads 55 or the upper ends of the columnar electrodes 30 and are welded onto the electrode pads 55 or the upper ends of the columnar electrodes 30. Accordingly, the connection parts 75 larger than the diameter (the thickness) in the X or Y direction of the columnar electrodes 70 are formed between the electrode pads 55 and the columnar electrodes 70, respectively. The connection parts 85 larger than the diameter (the thickness) in the X or Y direction of the columnar electrodes 80 are formed between the columnar electrodes 30 and the columnar electrodes 80, respectively. As a result, the connection strength between the electrode pads 55 and the columnar electrodes 70 and the connection strength between the columnar electrodes 30 and the columnar electrodes 80 can be increased. The columnar electrodes 70 and 80 are cut at the upper ends and maintain the upright states with the stiffness of the columnar electrodes 70 and 80 themselves.

Materials selected from the same range of materials of the columnar electrodes 30 described above can be used for the columnar electrodes 70 and 80. The materials of the columnar electrodes 70 and 80 can be the same material as that of the columnar electrodes 30 or may be a material different therefrom. With use of materials having a high hardness, for example, Cu, a CuPd alloy, or a material including Cu coated with Pd for the columnar electrodes 70 and 80, the columnar electrodes 70 and 80 are less likely to bend at the time of being covered with the resin layer 90 and are less likely to collapse.

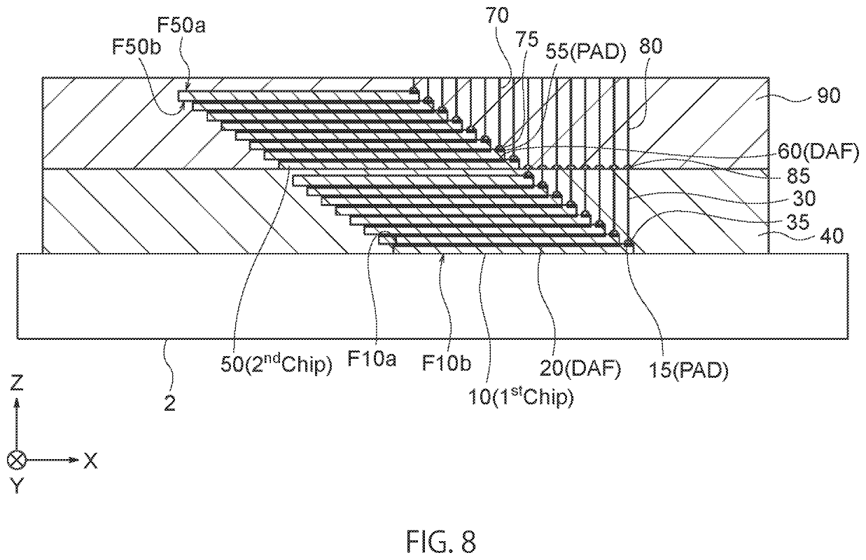

Next, the stacked body of the semiconductor chips 50 and the columnar electrodes 70 and 80 are covered with the resin layer 90 as illustrated in FIG. 8. A material of the resin layer 90 can be selected from the same range of materials of the resin layer 40 described above. The material of the resin layer 90 can be the same material as that of the resin layer or may be a material different therefrom. After formation of the resin layer 90, the resin layer 90 is heated by an oven or the like or the resin layer 90 is irradiated with ultraviolet rays to cure the resin layer 90.

Next, the resin layer 90 is polished using the CMP method, the mechanical polishing method, or the like until the columnar electrodes 70 and 80 are exposed. The structure illustrated in FIG. 8 is thereby obtained. Subsequently, the support substrate 2 is separated using heat, light of a laser, or the like. Alternatively, the support substrate 2 may be removed by polishing. Further, the structure illustrated in FIG. 8 is singulated by dicing. The semiconductor device 1 illustrated in FIG. 1A is thereby obtained. When the structure is diced while the support substrate 2 is left, the semiconductor device 1 illustrated in FIG. 1B is obtained.

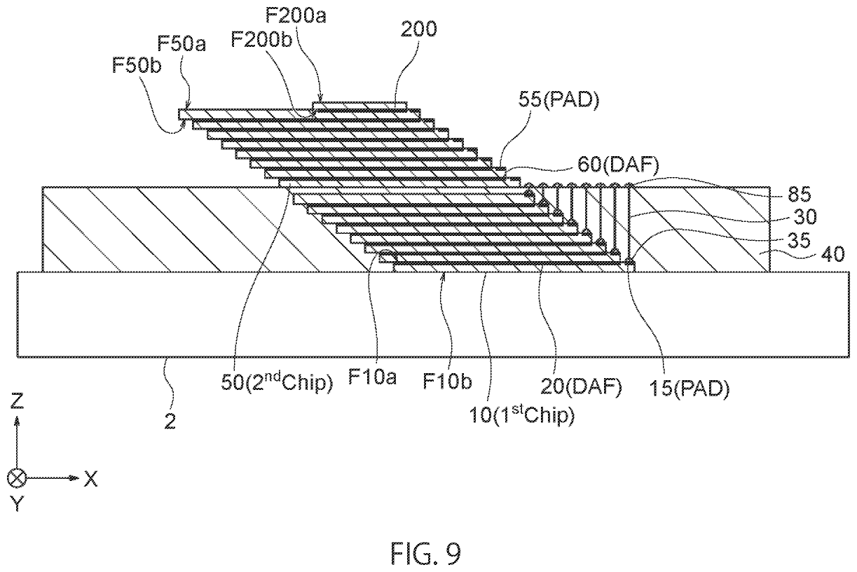

In a manufacturing method of the semiconductor devices 1 illustrated in FIGS. 2A and 2B, after the semiconductor chips 50 are stacked as illustrated in FIG. 6, the semiconductor chips 200 are further stacked on an uppermost one of the semiconductor chips 50 as illustrated in FIG. 9.

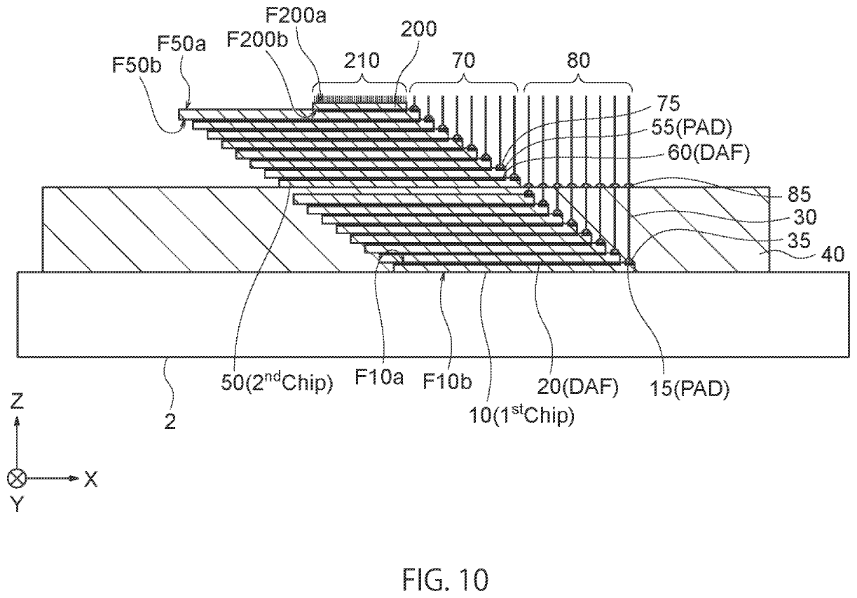

Next, metallic wires are bonded onto the electrode pads 55 of the semiconductor chips 50 by the wire bonding method and the metallic wires are drawn out in a substantially perpendicular direction (the Z direction) to the first faces F50a to form the columnar electrodes 70 as illustrated in FIG. 10. Furthermore, metallic wires are bonded onto the upper ends of the columnar electrodes 30 exposed from the resin layer 40 by the wire bonding method and the metallic wires are drawn out in the Z direction to form the columnar electrodes 80, respectively. Next, the columnar electrodes 210 are formed on each of the semiconductor chips 200 using a plating method. Alternatively, the columnar electrodes 210 may be formed by bonding metallic wires onto an electrode pad on each of the semiconductor chips 200 by the wire bonding method and drawing out the metallic wires in the substantially perpendicular direction to the first faces F200a. In this case, since the columnar electrodes 210 are also formed by the wire bonding method, the lower ends of the columnar electrodes 210 have a ball shape larger than the diameter (the thickness) in the X or Y direction of the columnar electrodes 210 on the electrode pads of the semiconductor chips 200 and are welded onto the electrode pads. This can increase the connection strength. The columnar electrodes 210 are cut at the upper ends and maintain the upright states with the stiffness of the columnar electrodes 210 themselves.

A material selected from the same range of materials of the columnar electrodes 30 described above can be used for the columnar electrodes 210. The material of the columnar electrodes 210 can be the same material as that of the columnar electrodes 30, 70, and 80 or may be a material different therefrom. With use of a material having a high hardness, for example, Cu, a CuPd alloy, or a material including Cu coated with Pd for the columnar electrodes 210, the columnar electrodes 210 are less likely to bend at the time of being covered with the resin layer 90 and are less likely to collapse.

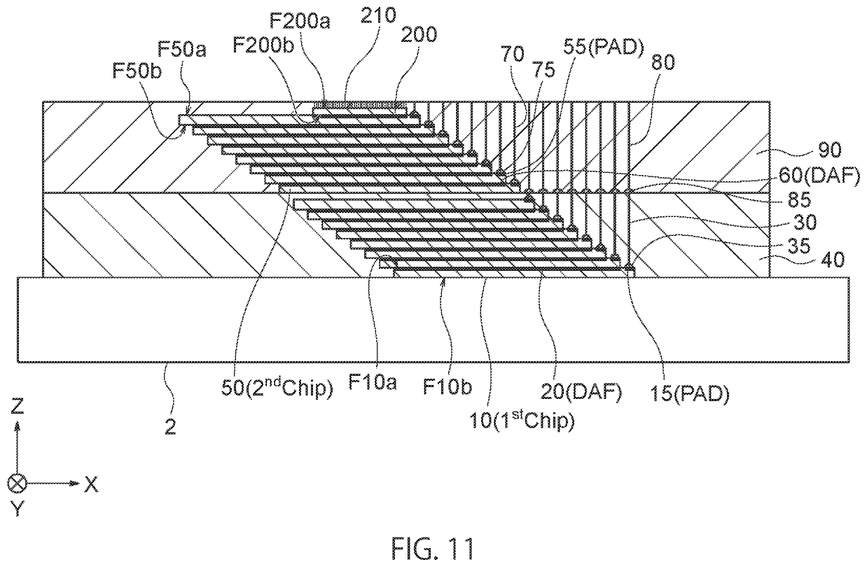

Next, the stacked body of the semiconductor chips 50 and the columnar electrodes 70, 80, and 210 are covered with the resin layer 90 as illustrated in FIG. 11. After formation of the resin layer 90, the resin layer 90 is heated by an oven or the like or irradiated with ultraviolet rays to cure the resin layer 90.

Next, the resin layer 90 is polished using the CMP method, the mechanical polishing method, or the like until the columnar electrodes 70, 80, and 210 are exposed. The structure illustrated in FIG. 11 is thereby obtained.

Subsequently, the redistribution layer 100 is formed on the resin layer 90. For example, an epoxy-based resin, a phenol-based resin, a polyimide-based resin, a polyamide-based resin, an acrylic-based resin, a PBO-based resin, a silicon-based resin, or a benzocyclobutene-based resin, or a mixed material or a composite material thereof is used as the insulating layers of the redistribution layer 100. For example, a simple substance of Cu, Ni, W, Au, Ag, Pd, Sn, Bi, Zn, Cr, Al, Ti, Ta, TiN, TaN, CrN, or the like, a composite material including two or more thereof, or an alloy including two or more thereof is used as the wiring layers of the redistribution layer 100.

Next, the support substrate 2 is separated using heat, light of a laser, or the like. Alternatively, the support substrate 2 may be removed by polishing.

Further, the metallic bumps 150 are formed on the redistribution layer 100. The metallic bumps 150 can be formed using, for example, ball mounting, the plating method, or a printing method. For example, a simple substance of Sn, Ag, Cu, Au, Pd, Bi, Zn, Ni, Sb, In, or Ge, or a composite membrane or an alloy including two or more thereof is used as the metallic bumps 150.

The structure illustrated in FIG. 11 is subsequently singulated by dicing. The semiconductor device 1 illustrated in FIG. 2A is thereby completed. When the structure is diced while the support substrate 2 is left, the semiconductor device 1 illustrated in FIG. 2B is obtained.

The semiconductor device 1 having the configuration described above was mounted on a wiring substrate and a thermal cycle test was performed. The thermal cycle test had a cycle of −55° C. (30 minutes (min)), 25° C. (5 min), and 125° C. (30 min) and was performed 3000 cycles. No abnormality was found at connection parts in the semiconductor device 1 according to the present embodiment even after the 3000 cycles.

While formed by the wire bonding method as an example in the embodiment described above, the columnar electrodes 30, 70, 80, and 210 may be formed by the plating method. For example, after holes reaching the electrode pads 15 and 55 are formed in the resin layers 40 and 90, a metallic material is embedded in the holes by the plating method. Accordingly, the columnar electrodes 30, 70, 80, and 210 can be formed by the plating method. The columnar electrodes 30, 70, 80, and 210 may be formed using both the plating method and the wire bonding method.

The columnar electrodes 30, 70, 80, and 210 according to the present embodiment and wires that are formed by a normal wire bonding method and that directly connect electrode pads of semiconductor chips to each other may be mixed. Alternatively, wires that directly connect semiconductor chips to each other, columnar electrodes formed by the wire bonding method, and columnar electrodes formed by the plating method may be mixed.

As described above, according to the present embodiment, the columnar electrodes 30 and 80 electrically connected to the electrode pads 15 of the semiconductor chips 10 stacked on lower tiers are formed being divided into the columnar electrodes 30 on lower tiers and the columnar electrodes 80 on upper tiers along with the stacking process of the semiconductor chips 10 and 50. Therefore, the present embodiment can form the columnar electrodes 30 and 80 substantially long while suppressing collapse or interference at the time of formation of the resin layers 40 and 90.

The columnar electrodes 30 are connected to the semiconductor chips 10 and are covered with the resin layer 40. The semiconductor chips 50 are subsequently stacked on the resin layer 40 flattened, and the columnar electrodes 80 are formed to be respectively connected to the columnar electrodes 30. In this way, the upper-tier columnar electrodes 80 are formed after the lower-tier columnar electrodes 30 are sealed with the resin layer 40. Therefore, the columnar electrodes 30 are not collapsed or inclined due to formation of the columnar electrodes 80. Since the columnar electrodes 80 are erected from the resin layer 40 flattened and cured, the columnar electrodes 80 are also less likely to collapse or incline. The locations of the upper ends of the columnar electrodes 80 are stabilized and displacements in the location are less likely to occur. Furthermore, the connection parts 85 thicker than the columnar electrodes 30 and 80 are formed on the lower ends of the columnar electrodes 80, respectively. Therefore, the connection resistance values between the columnar electrodes 30 and the columnar electrodes 80 can be reduced. Accordingly, the columnar electrodes 30 and 80 can be electrically connected with low resistances from the upper ends of the columnar electrodes 80 to the electrode pads 15 of the semiconductor chips 10, respectively. The connection parts 85 can also improve the mechanical connection strength between the columnar electrodes 30 and the columnar electrodes 80.

As a result, collapse or interference of the columnar electrodes 30 and 80 can be suppressed and the columnar electrodes can be formed of substantially long wires.

When the semiconductor device 1 has a configuration in which the material of the resin layer 40 is different from the material of the resin layer 90 and the resin layer 40 and the resin layer 90 have opposite stresses, this leads to suppression in warp of the semiconductor device 1. A difference in the stress between the resin layer 40 and the resin layer 90 can be adjusted with the respective thicknesses. For example, when the stress of the resin layer 40 is smaller than the stress of the resin layer 90 while the resin layer 40 and the resin layer 90 have opposite stresses, it suffices to form the thickness of the resin layer 40 to be correspondingly larger than the thickness of the resin layer 90. For example, the warp of the semiconductor device 1 may be suppressed by setting a value of “elastic modulus thermal expansion coefficient” of the resin layer 90 as the upper layer to be smaller than a value of “elastic modulus×thermal expansion coefficient” of the resin layer 40.

The support substrate 2 may be left as it is without being removed as illustrated in FIG. 11. In this case, the package of the semiconductor device 1 is diced along with the support substrate 2. The second face F10b of the lowermost semiconductor chip 10 can be protected by the support substrate 2.

### Second Embodiment

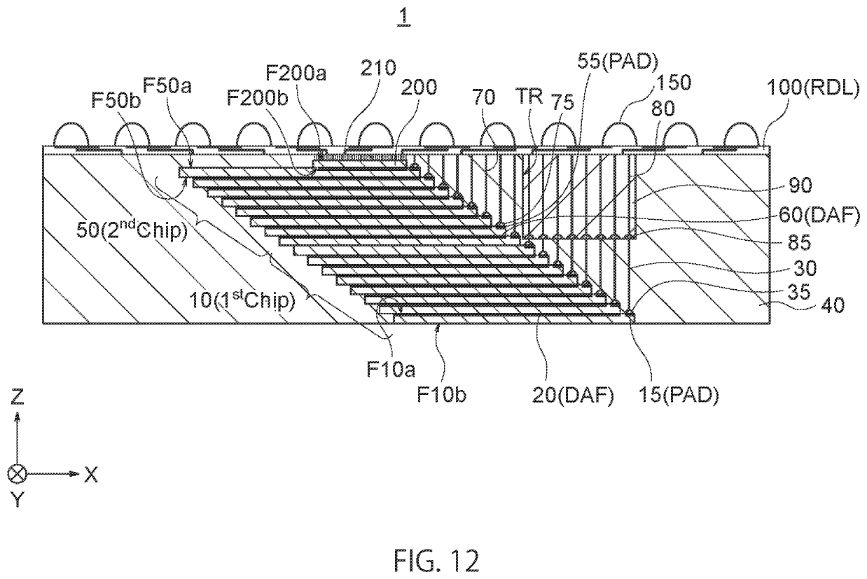

FIG. 12 is a sectional view illustrating an example of a configuration of the semiconductor device 1 according to a second embodiment. In the second embodiment, the semiconductor chips 10 and the semiconductor chips 50 are continuously stacked. The lowermost semiconductor chip 50 is stacked on the uppermost semiconductor chip 10. While the adhesive layer 60 is provided between the uppermost semiconductor chip 10 and the lowermost semiconductor chip 50, the resin layer 40 or 90 is not interposed therebetween.

The semiconductor chips 10 and 50 are covered as a whole with the resin layer 40. However, trenches TR are provided in the resin layer 40 above the electrode pads 15 of the semiconductor chips 10 and the resin layer 90 is provided in the trenches TR.

The resin layer 90 is identical to that in the first embodiment in covering the columnar electrodes 80 and exposing the tops of the columnar electrodes 80. However, the resin layer 90 is filled only in the trenches TR and does not cover the semiconductor chips 50 and the columnar electrodes 70.

Meanwhile, the resin layer 40 covers the semiconductor chips 10 and 50 and the columnar electrodes 30 and 70. The resin layer 40 exposes the tops of the columnar electrodes 70 on the upper surface. The resin layer 40 exposes the tops of the columnar electrodes 30 on bottom portions of the trenches TR. Therefore, at the bottom portions of the trenches TR, the columnar electrodes 80 are electrically connected to the tops of the columnar electrodes 30 via the connection parts 85, respectively.

The columnar electrodes 30, 70, and 80 can have same configurations as those in the first embodiment. Therefore, the columnar electrodes 30 are connected to the electrode pads 15 of the semiconductor chips 10 and extend in the stacking direction (the Z direction) of the semiconductor chips 10. The columnar electrodes 70 are connected to the electrode pads 55 of the semiconductor chips 50 and extend in the stacking direction (the Z direction) of the semiconductor chips 50. The columnar electrodes 80 are respectively connected to the tops of the columnar electrodes 30 exposed in the trenches TR of the resin layer 40 and extend in the Z direction.

The rest of the configuration in the second embodiment may be identical to the corresponding configuration in the first embodiment. The semiconductor device 1 illustrated in FIG. 12 has a configuration corresponding to that illustrated in FIG. 2A and further includes the semiconductor chips 200, the redistribution layer 100, the metallic bumps 150, and the like. The configurations of the semiconductor chips 200, the redistribution layer 100, the metallic bumps 150, and the like may be identical to the configurations of those illustrated in FIG. 2A. When the semiconductor chips 200, the redistribution layer 100, and the metallic bumps 150 are omitted from the configuration illustrated in FIG. 12, the semiconductor device 1 has a configuration corresponding to FIG. 1A. The semiconductor device 1 according to the second embodiment may have the support substrate 2 as illustrated in FIG. 1B or 2B.

A manufacturing method of the semiconductor device 1 according to the second embodiment is explained next.

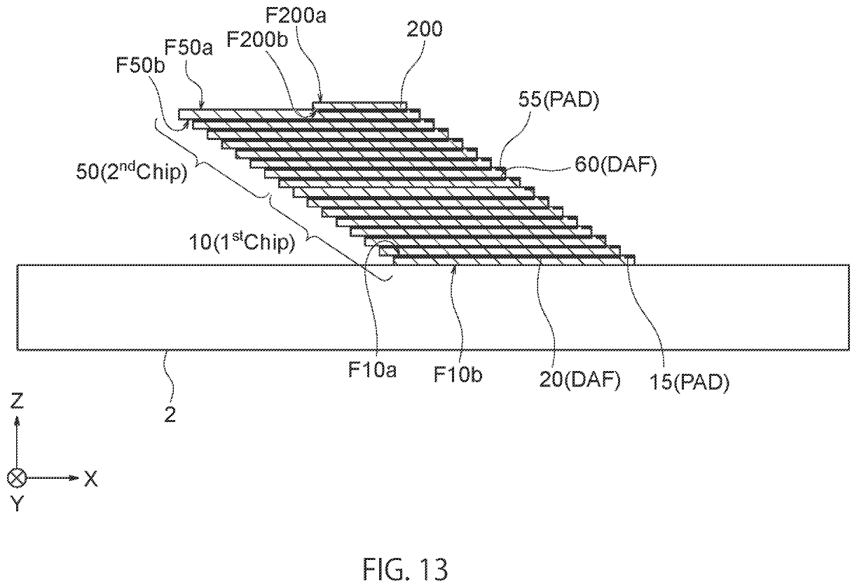

FIGS. 13 to 20 are sectional views illustrating an example of the manufacturing method of the semiconductor device 1 according to the second embodiment.

First, a plurality of semiconductor chips 10 are stacked on a support substrate 2 as illustrated in FIG. 13. At this time, each of the semiconductor chips 10 is stuck onto another semiconductor chip 10 with the adhesive layer 20. Subsequently, a plurality of semiconductor chips 50 are stacked on the semiconductor chips 10. At this time, each of the semiconductor chips 50 is stuck onto another semiconductor chip 10 or 50 with the adhesive layer 60. The lowermost semiconductor chip 50 is stuck onto the uppermost semiconductor chip 10 with the adhesive layer 60. Next, the semiconductor chips 200 are stuck onto the uppermost semiconductor chip 50 with the adhesive layer 60. The semiconductor chips 10, 50, and 200 are stacked to be displaced in the X direction so as not to overlap with the electrode pads 15 and 55 of semiconductor chips located thereunder, respectively. The structure illustrated in FIG. 13 is thereby obtained.

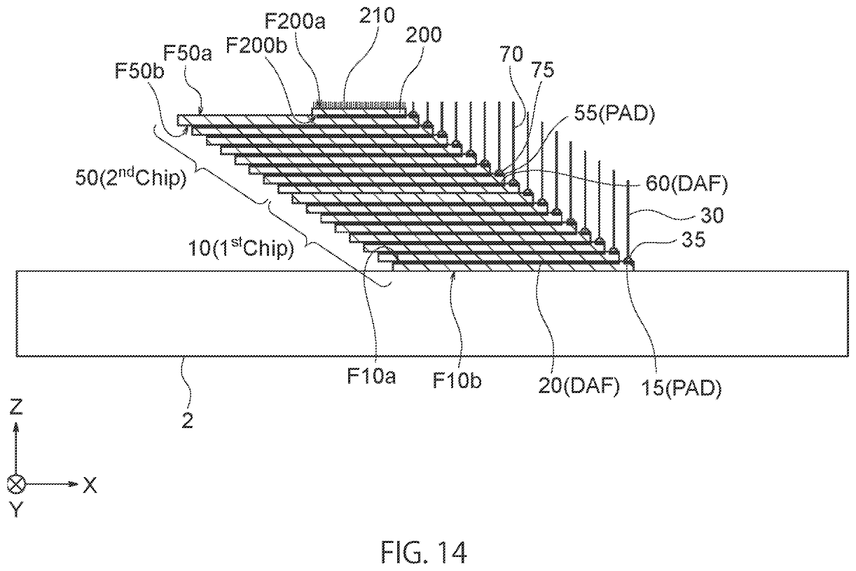

Next, metallic wires are bonded onto the electrode pads 15 and 55 of the semiconductor chips 10 and 50 by the wire bonding method and the metallic wires are drawn out in a substantially perpendicular direction to the first faces F10a and F50a to form the columnar electrodes 30 and 70, respectively, as illustrated in FIG. 14. Since the columnar electrodes 30 and 70 are formed by the wire bonding method, the lower ends of the columnar electrodes 30 and 70 are welded on the electrode pads 15 and 55 in a ball shape larger than the diameter (the thickness) in the X or Y direction of the columnar electrodes 30 and 70, respectively. Accordingly, the connection parts 35 larger than the diameter (the thickness) in the X or Y direction of the columnar electrodes 30 are formed between the electrode pads 15 and the columnar electrodes 30, respectively. The connection parts 75 larger than the diameter (the thickness) in the X or Y direction of the columnar electrodes 70 are formed between the electrode pads 55 and the columnar electrodes 70, respectively. As a result, the connection strength between the electrode pads 15 and the columnar electrodes 30 and the connection strength between the electrode pads 55 and the columnar electrodes 70 can be increased. The columnar electrodes 30 and 70 are cut at the upper ends and maintain the upright states with the stiffness of the columnar electrodes 30 and 70 themselves.

Further, metallic wires are bonded on the electrode pads of the semiconductor chips 200 by the wire bonding method and the metallic wires are drawn out in a substantially perpendicular direction to the first faces F200a to form the columnar electrodes 210. Alternatively, the columnar electrodes 210 may be previously formed as metallic pillars on each of the semiconductor chips 200 and the semiconductor chips 200 having the columnar electrodes 210 may be stuck onto the uppermost semiconductor chip 500.

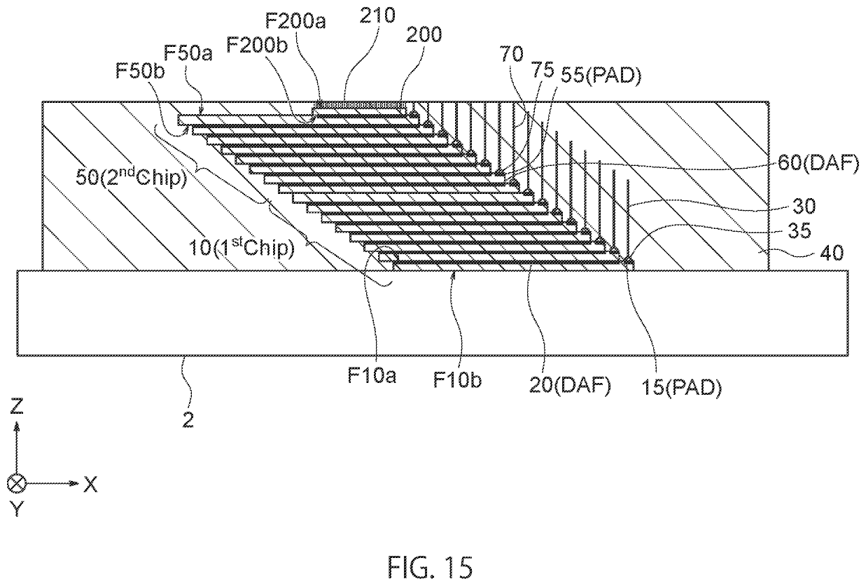

Next, the semiconductor chips 10, 50, and 200 and the columnar electrodes 30, 70, and 210 are covered with the resin layer 40 as illustrated in FIG. 15. Next, the resin layer 40 is heated by an oven or the like or the resin layer 40 is irradiated with ultraviolet rays to cure the resin layer 40.

Next, the resin layer 40 is polished using the CMP method, the mechanical polishing method, or the like until the columnar electrodes 70 and 210 are exposed. Accordingly, the structure illustrated in FIG. 15 is obtained.

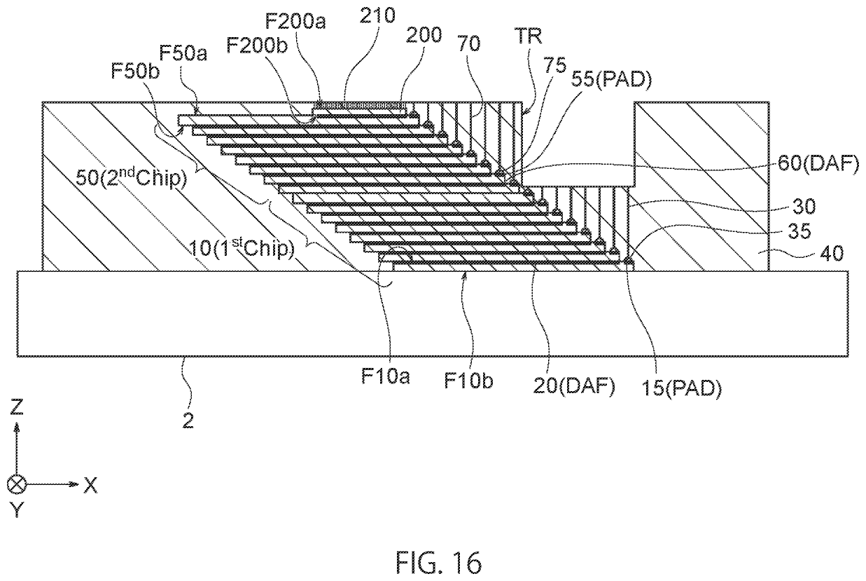

Next, portions of the resin layer 40 located above the electrode pads 15 and the columnar electrodes 30 are polished using a blade, a laser, or the like to form the trenches TR in the resin layer 40 as illustrated in FIG. 16. The trenches TR extend in a substantially parallel direction (the Y direction) to sides of the semiconductor chips 10 and 50 on which the electrode pads 15 and 55 are provided and are formed continuously also in other semiconductor packages (not illustrated) adjacent in the Y direction.

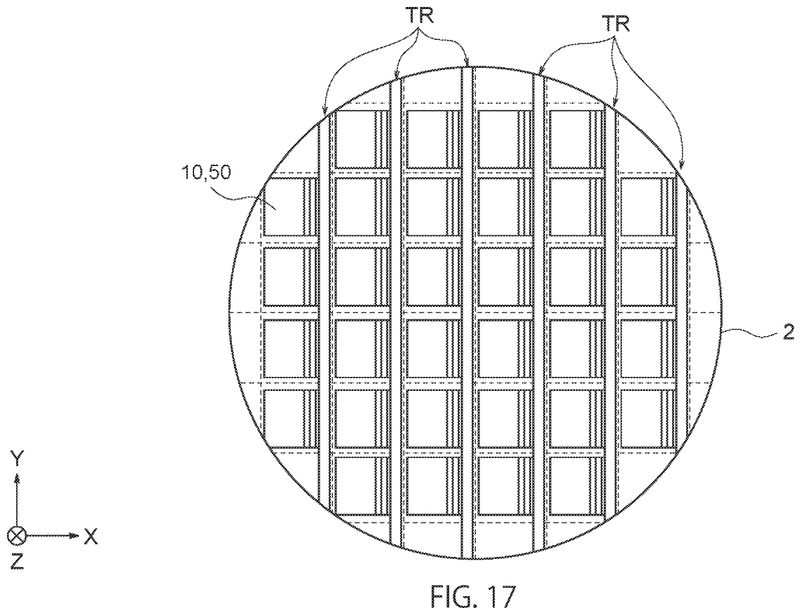

FIG. 17 is a schematic plan view of a structure formed in the process illustrated in FIG. 16. As illustrated in FIG. 17, the trenches TR are formed in a substantially parallel direction to the extending direction (the Y direction) of the sides of the semiconductor chips 10 and 50 on which the electrode pads 15 and 55 are respectively provided. That is, the trenches TR are formed to extend in a direction (the Y direction) orthogonal to a direction in which the semiconductor chips 10 and 50 are displaced.

As illustrated in FIG. 16, the trenches TR expose the upper ends of the columnar electrodes 30 on the bottom portions. When a blade is used, the trenches TR are formed in the manner of lines as illustrated in FIG. 17. When a laser is used, the trenches TR may be formed only in a region in which the semiconductor chips 10 and 50 are located.

In the present embodiment, the trenches TR are formed after the resin layer 40 is entirely polished using the CMP method or the mechanical polishing method. However, the resin layer 40 may be entirely polished using the CMP method or the mechanical polishing method after the trenches TR are formed.

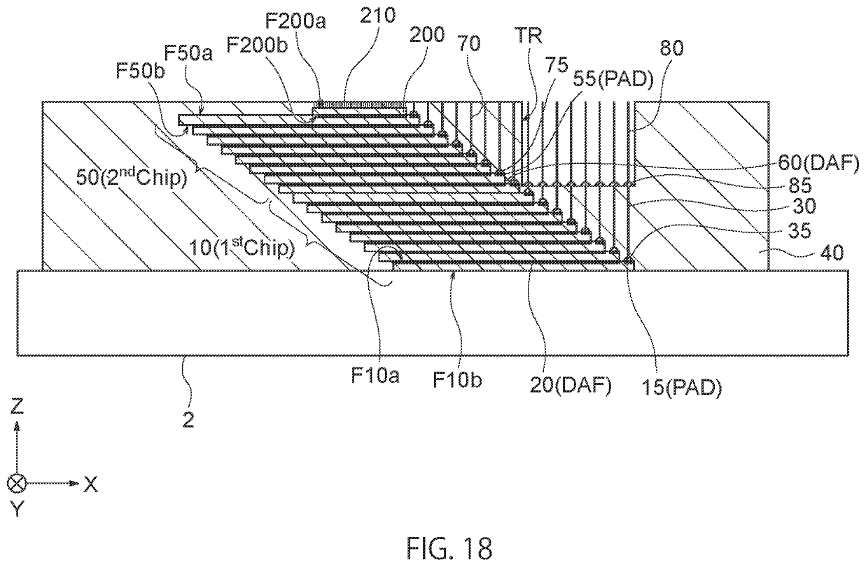

Next, metallic wires are bonded onto the upper ends of the columnar electrodes 30 exposed on the bottom portions of the trenches TR by the wire bonding method and the metallic wires are drawn out in the Z direction to form the columnar electrodes 80, respectively, as illustrated in FIG. 18. Since the columnar electrodes 80 are formed by the wire bonding method, the lower ends of the columnar electrodes 80 are welded onto the upper ends of the columnar electrodes 30 in a ball shape larger than the diameter (the thickness) in the X or Y direction of the columnar electrodes 80 on the upper ends of the columnar electrodes 30, respectively. Accordingly, the connection parts 85 larger than the diameter (the thickness) in the X or Y direction of the columnar electrodes 80 are formed between the columnar electrodes 30 and the columnar electrodes 80, respectively. As a result, the connection strength between the columnar electrodes 30 and the columnar electrodes 80 can be increased. The columnar electrodes 80 are cut at the upper ends and maintain the upright states with the stiffness of the columnar electrodes 80 themselves. The material of the columnar electrodes 80 is as described above and the columnar electrodes 80 are less likely to bend at the time of being covered with the resin layer 90 and are less likely to collapse.

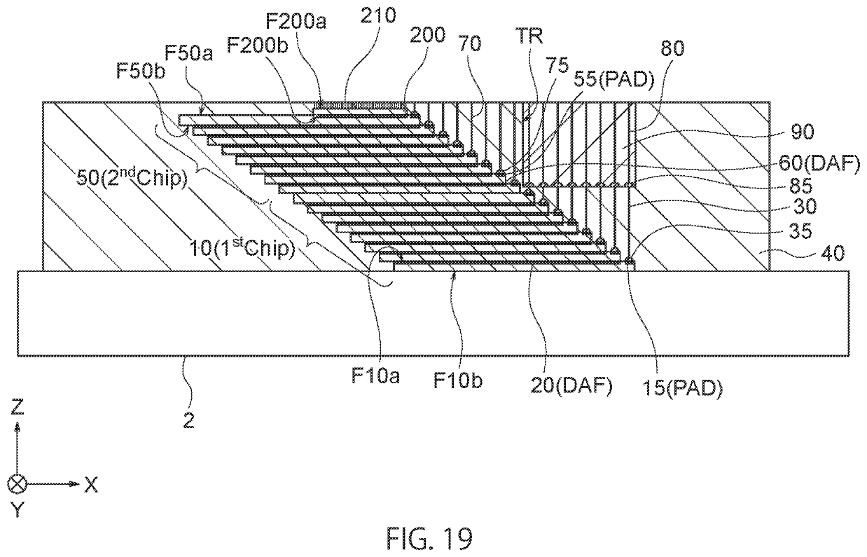

Next, the material of the resin layer 90 is filled in the trenches TR to cover the columnar electrodes 80 as illustrated in FIG. 19. Next, the resin layer 90 is heated by an oven or the like or the resin layer 90 is irradiated with ultraviolet rays to cure the resin layer 90.

Next, the resin layer 90 is polished using the CMP method, the mechanical polishing method, or the like until the columnar electrodes 70, 80, and 210 are exposed. Accordingly, the structure illustrated in FIG. 19 is obtained.

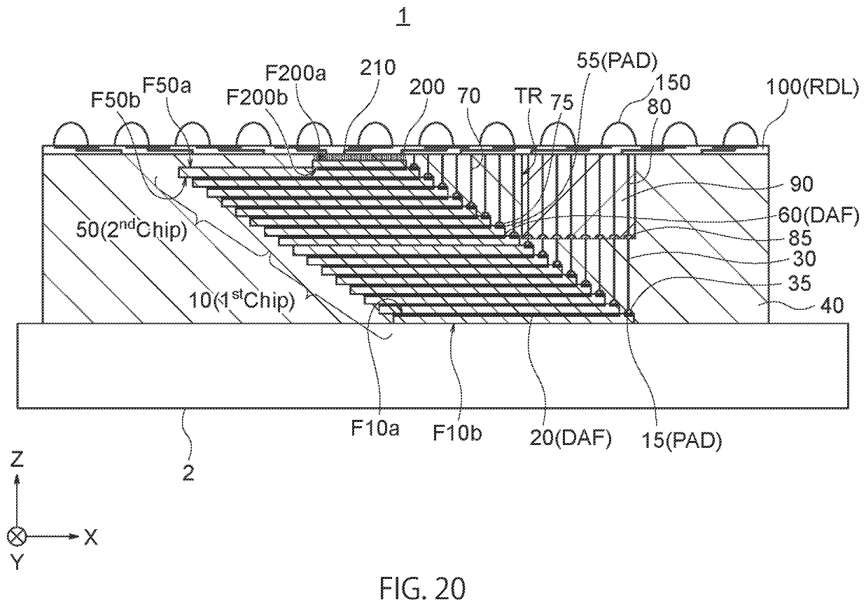

Next, the redistribution layer 100 is formed on the resin layer 90 as illustrated in FIG. 20. Next, the support substrate 2 is separated using heat or light of a laser, or the like. Alternatively, the support substrate 2 may be removed by polishing.

Further, the metallic bumps 150 are formed on the redistribution layer 100. The metallic bumps 150 can be formed using, for example, ball mounting, the plating method, or the printing method.

Subsequently, the structure illustrated in FIG. 20 is singulated by dicing. The semiconductor device 1 illustrated in FIG. 12 is thereby completed.

The redistribution layer 100 and the metallic bumps 150 may be omitted similarly in the mode illustrated in FIG. 1A or 1B.

In the second embodiment, the resin layer 90 is filled in the trenches TR provided in portions of the resin layer 40. Therefore, the volume of the resin layer 90 can be adjusted according to the width or depth of the trenches TR. The warp of the resin layer 40 can be suppressed by an adjustment of the volume of the resin layer 90.

Other configurations of the second embodiment may be identical to corresponding ones of the first embodiment.

Also in the second embodiment, the columnar electrodes 30 and 80 electrically connected to the electrode pads 15 of the semiconductor chips 10 stacked on lower tiers are formed being divided into the columnar electrodes 30 on the lower tiers and the columnar electrodes 80 on the upper tiers. Accordingly, the present embodiment can form the columnar electrodes 30 and 80 substantially long while suppressing collapse or interference at the time of formation of the resin layers 40 and 90. The second embodiment can also achieve other effects of the first embodiment.

### Third Embodiment

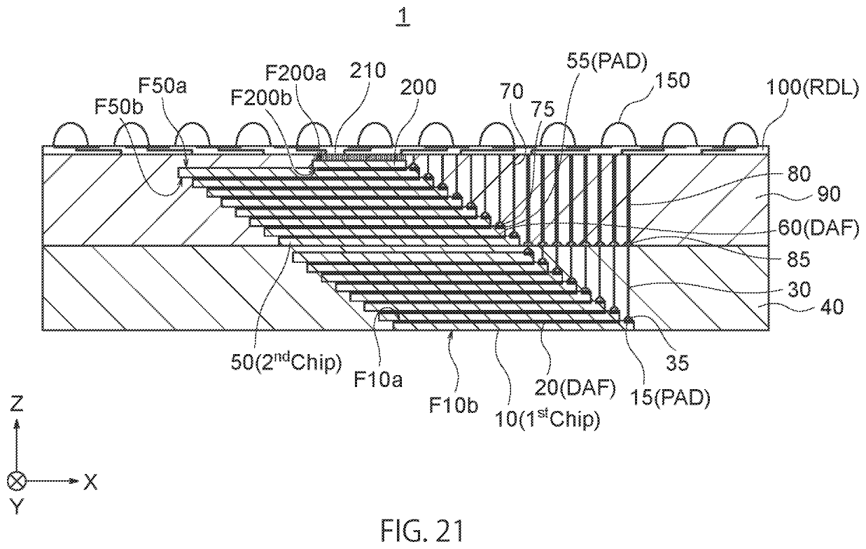

FIG. 21 is a sectional view illustrating a configuration example of the semiconductor device 1 according to a third embodiment. In the third embodiment, the columnar electrodes 80 are thicker than those in the first embodiment. The size (sectional area) on a cross section in a perpendicular direction (the X or Y direction) to the extending direction of the columnar electrodes 80 differs between the columnar electrodes 80 and the columnar electrodes 30 and 70. The columnar electrodes 80 are thicker and larger in the sectional area described above than the columnar electrodes 30 and 70.

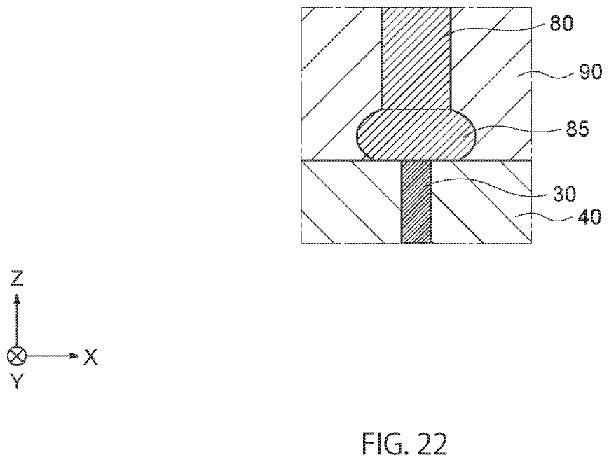

FIG. 22 is a schematic sectional view illustrating a configuration example of the columnar electrodes 30 and 80 and the connection parts 85. The columnar electrodes 80 are thicker than the columnar electrodes 30 and are thinner than the connection parts 85. That is, the sectional area of the columnar electrodes 80 in the X-Y plane is larger than the sectional area of the columnar electrodes 30 and is smaller than the sectional area of the connection parts 85.

Due to the larger thickness of the columnar electrodes 80, the resistance value of the columnar electrodes 80 is decreased. This decreases the resistance value of the columnar electrodes 80 and 30 from the redistribution layer 100 to the electrode pads 15 and electrical characteristics of the semiconductor device 1 can be improved. Other configurations of the third embodiment may be identical to corresponding ones of the first embodiment. Therefore, the third embodiment can also achieve effects of the first embodiment.

### Fourth Embodiment

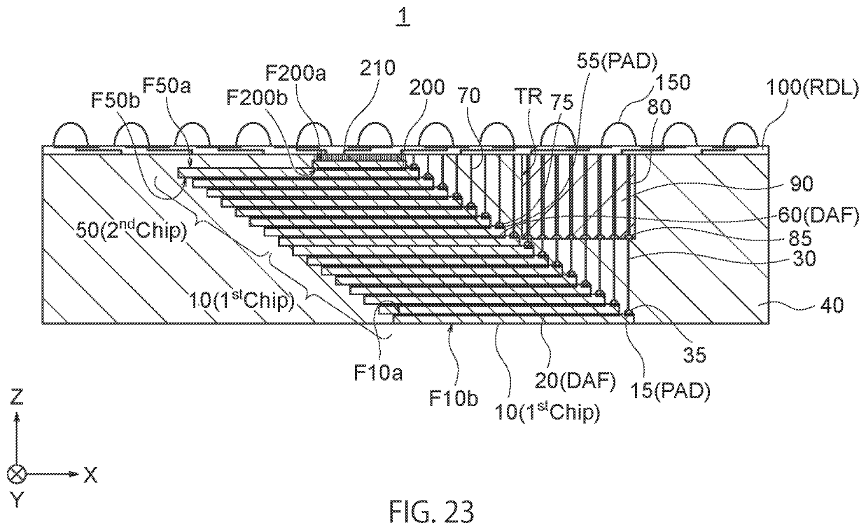

FIG. 23 is a sectional view illustrating a configuration example of the semiconductor device 1 according to a fourth embodiment. The fourth embodiment is an embodiment in which the columnar electrodes 80 according to the third embodiment are applied to the second embodiment. That is, the columnar electrodes 80 are larger in the sectional area on the X-Y plane than the columnar electrodes 30 and 70 and are smaller than the sectional area of the connection parts 85. Accordingly, the resistance value of the columnar electrodes 80 and 30 from the redistribution layer 100 to the electrode pads 15 can be decreased and the electric characteristics of the semiconductor device 1 can be improved. Other configurations of the fourth embodiment may be identical to corresponding ones of the second embodiment. Therefore, the fourth embodiment can also achieve effects of the second embodiment.

In the third and fourth embodiments, the resistance value of the columnar electrodes 80 is decreased by thickening the columnar electrodes 80. However, the resistance value of the columnar electrodes 80 may be decreased by changing the material of the columnar electrodes 80 to a material of a lower resistance than that of the material of the columnar electrodes 30 and 70.

### Fifth Embodiment

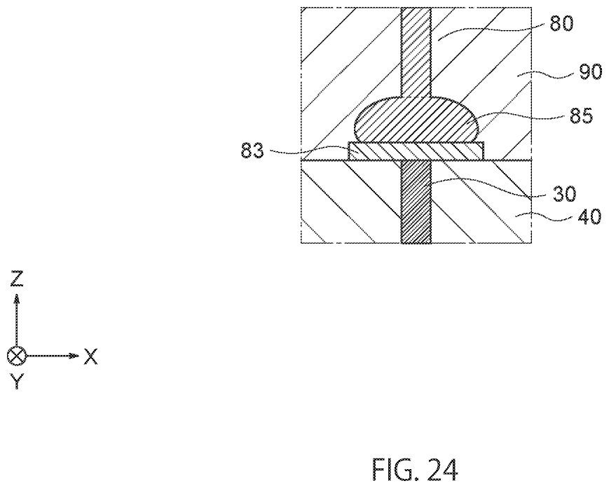

FIG. 24 is a sectional view illustrating a configuration example of the semiconductor device 1 according to a fifth embodiment. The semiconductor device 1 according to the fifth embodiment is different from that according to the first embodiment in that an additional pad 83 is provided between the connection part 85 and the associated columnar electrode 30. The additional pad 83 is provided on a top portion of the columnar electrode 30 exposed from the resin layer 40 and has a larger area than the exposed area of the top portion of the columnar electrode 30 in the X-Y plane.

For example, a conductive metal such as a simple substance of Cu, Ni, W, Au, Ag, Pd, Sn, Bi, Zn, Al, Ti, TiN, Cr, CrN, Ta, TaN, or the like, a composite membrane including two or more thereof, or an alloy including two or more thereof is used as the additional pad 83. The additional pad 83 can increase the connection strength between the columnar electrode 30 and the corresponding columnar electrode 80 and can improve the reliability. It suffices to form the additional pad 83 on the columnar electrode 30 and the resin layer 40 using, for example, a vapor deposition method, a sputtering method, an electroplating method, or an electroless plating method. For example, a composite membrane such as Ti/Ni/Au can be formed using the sputtering method. A composite membrane such as Ni/Pd/Au can be formed using the electroless plating method.

The additional pad 83 may be provided between all the columnar electrodes 30 and the connection parts 85 of all the columnar electrodes 80. Further, the additional pad 83 may be also applied to the second to fourth embodiments.

### Sixth Embodiment

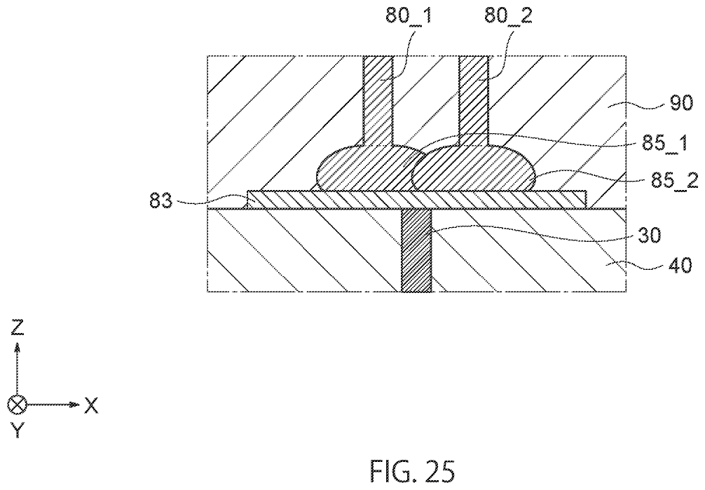

FIG. 25 is a sectional view illustrating a configuration example of the semiconductor device 1 according to a sixth embodiment. In the semiconductor device 1 according to the sixth embodiment, a plurality of columnar electrodes 80_1 and 80_2 are connected to correspond to one columnar electrode 30. The number of the columnar electrodes 80_1 and 80_2 is not limited to two and may be three or more. The columnar electrodes 80_1 and 80_2 are connected to the associated additional pad 83 via connection parts 85_1 and 85_2, respectively, and are electrically connected to one columnar electrode 30. The connection parts 85_1 and 85_2 are connected in common to the additional pad 83. Therefore, the additional pad 83 has a larger area than the exposed area of the top portion of the columnar electrode 30 in the X-Y plane and has a larger area than the sectional area of the connection parts 85_1 and 85_2 in the X-Y plane. A structure in which one columnar electrode is conversely connected to the columnar electrodes 80_1 and 80_2 is applicable. A structure in which one columnar electrode is connected via the additional pad 83 is also applicable.

The columnar electrodes 80_1 and 80_2 may be provided to correspond to each of the columnar electrodes 30 or each of the additional pads 83.

### Seventh Embodiment

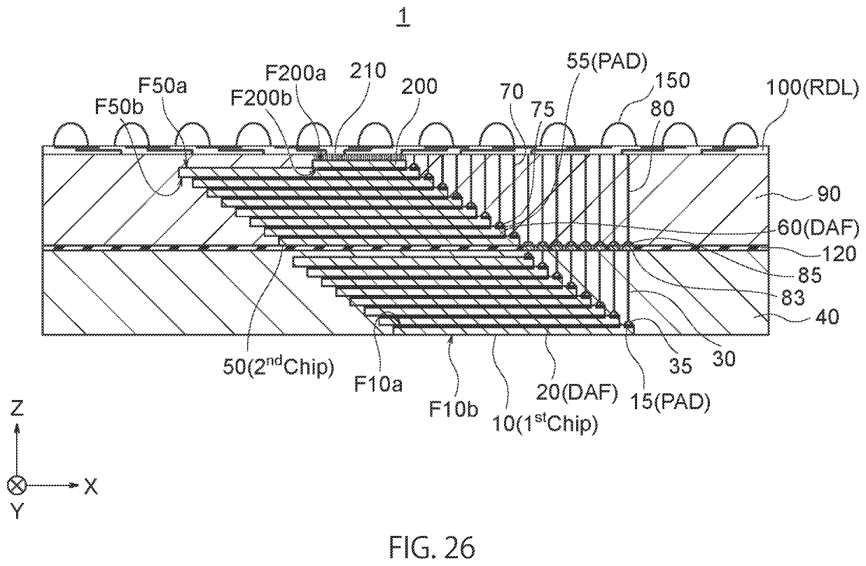

FIG. 26 is a sectional view illustrating a configuration example of the semiconductor device 1 according to a seventh embodiment. The semiconductor device 1 according to the seventh embodiment further includes an insulating layer 120 between the resin layer 40 and the resin layer 90 or the semiconductor chips 50. While provided on the resin layer 40, the insulating layer 120 is removed in regions of the additional pads 83 and the connection parts 85.

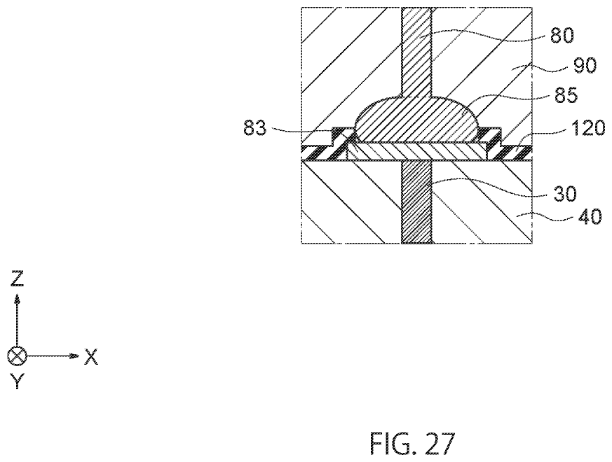

FIG. 27 is a schematic sectional view illustrating a configuration example of one of the additional pads 83, the associated connection part 85, and a periphery thereof. The insulating layer 120 covers the end portion of the additional pad 83 and is not provided in a central portion of the additional pad 83. Therefore, the connection part 85 can be connected to the surface of the additional pad 83. For example, a resin such as a phenol-based resin, a polyimide-based resin, a polyamide-based resin, an acrylic-based resin, an epoxy-based resin, a PBO-based resin, a silicon-based resin, or a benzocyclobutene-based resin, or a mixed material or a composite material thereof is used as the insulating layer 120.

The insulating layer 120 is formed after the columnar electrodes 30 are exposed and the additional pads 83 are formed. The insulating layer 120 can maintain an electrical insulation property between adjacent ones of the additional pads 83 and improve the reliability of the semiconductor device 1.

With provision of the insulating layer 120 between the resin layer 40 and the resin layer 90, the adhesion between the resin layer 40 and the resin layer 90 can be improved. Furthermore, the insulating layer 120 can improve the adhesion of the adhesive layer 60 stuck onto the second face F50b of the lowermost semiconductor chip 50. It is preferable that the elastic modulus of the insulating layer 120 be lower than those of the resin layer 40 and the resin layer 90. Accordingly, the insulating layer 120 can absorb expansion and contraction of the resin layers 40 and 90 and suppress warp of the semiconductor device 1.

Other configurations of the seventh embodiment may be identical to corresponding ones of the first embodiment. Therefore, the seventh embodiment can also achieve effects of the first embodiment.

### Eighth Embodiment

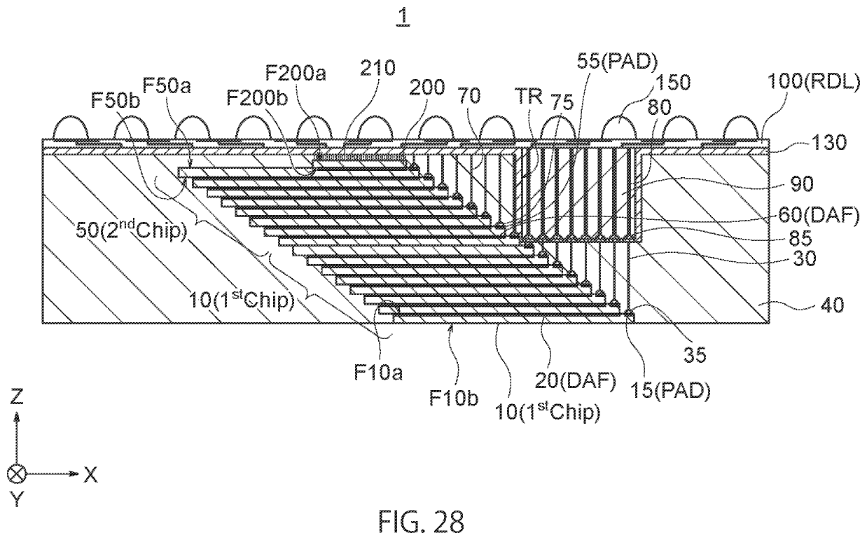

FIG. 28 is a sectional view illustrating a configuration example of the semiconductor device 1 according to an eighth embodiment. The semiconductor device 1 according to the eighth embodiment further includes an insulating layer 130 between the resin layer 40 and the redistribution layer 100 and between the resin layer 40 and the resin layer 90. While covering the inner surfaces of the trenches TR and being provided on the resin layer 40 between the resin layer 40 and the resin layer 90, the insulating layer 130 is removed in the regions of the additional pads 83 and the connection parts 85.

The insulating layer 130 covers the end portions of the additional pads 83 and is not provided in the central parts of the additional pads 83 similarly to the insulating layer 120. Therefore, the connection parts 85 can be respectively connected to the surfaces of the associated additional pads 83. For example, a resin such as a phenol-based resin, a polyimide-based resin, a polyamide-based resin, an acrylic-based resin, an epoxy-based resin, a PBO-based resin, a silicon-based resin, or a benzocyclobutene-based resin, or a mixed material or a composite material thereof is used as the insulating layer 130.

After formation of the trenches TR, the upper ends of the columnar electrodes 30 are exposed, the additional pads 83 are formed, and the insulating layer 130 is subsequently formed. The insulating layer 130 can maintain electrical isolation between adjacent ones of the additional pads 83 and improve the reliability of the semiconductor device 1.

With provision of the insulating layer 130 between the resin layer 40 and the resin layer 90, the adhesion between the resin layer 40 and the resin layer 90 can be improved. The insulating layer 130 also can improve the adhesion between the resin layer 40 and the redistribution layer 100. It is preferable that the elastic modulus of the insulating layer 130 be lower than those of the resin layers 40 and 90 and the redistribution layer 100. Accordingly, the insulating layer 130 can absorb expansion and contraction of the resin layers 40 and 90 and the redistribution layer 100 and suppress warp of the semiconductor device 1.

Other configurations of the eighth embodiment may be identical to corresponding ones of the second embodiment. Therefore, the eighth embodiment can also achieve effects of the second embodiment.

### Ninth Embodiment

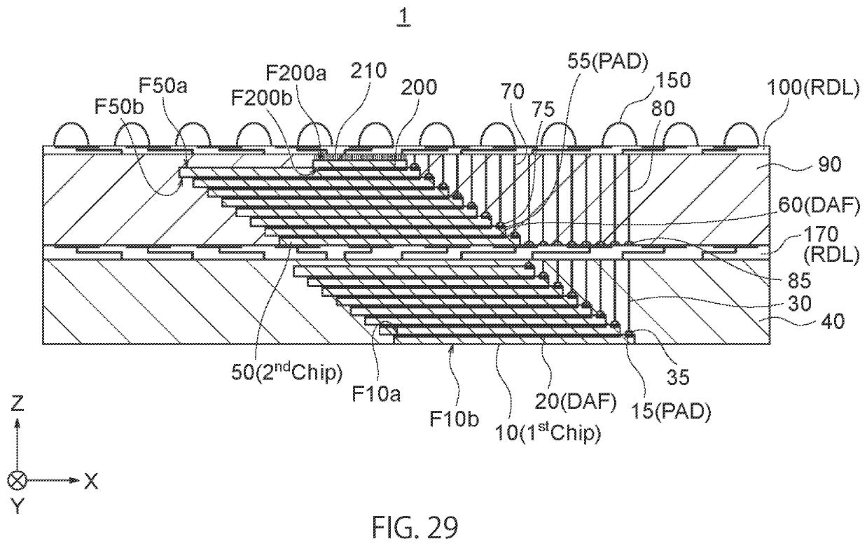

FIGS. 29 to 31 are sectional views respectively illustrating configuration examples of the semiconductor device 1 according to a ninth embodiment. The semiconductor device 1 according to the ninth embodiment further includes a redistribution layer 170 between the resin layer 40 and the resin layer 90 and between the resin layer 40 and the lowermost semiconductor chip 50. The wiring layers of the redistribution layer 170 are electrically connected to the columnar electrodes 30 on the side of the resin layer 40. That is, the top portions of the columnar electrodes 30 are electrically connected to the wiring layers on the side of the rear surface of the redistribution layer 170. The wiring layers of the redistribution layer 170 are electrically connected to the columnar electrodes 80 on the side of the resin layer 90. That is, the lower ends of the columnar electrodes 80 are electrically connected to the wiring layers on the side of the front surface of the redistribution layer 170. The material of the redistribution layer 170 may be identical to that of the redistribution layer 100.

The redistribution layer 170 redistributes the columnar electrodes 30 to be electrically connected to the columnar electrodes 80, respectively. Therefore, the distance between adjacent ones of the columnar electrodes 80 is not restricted by the distance between adjacent ones of the columnar electrodes 30. That is, the flexibility in arrangement of the columnar electrodes 80 with respect to the columnar electrodes 30 is increased and the flexibility in design is increased. Accordingly, the columnar electrodes 80 can be arranged at different locations from those of the columnar electrodes 30 as viewed from the Z direction. The provision of the redistribution layer 170 between the resin layer 40 and the resin layer 90 can increase the adhesion between the resin layer 40 and the resin layer 90.

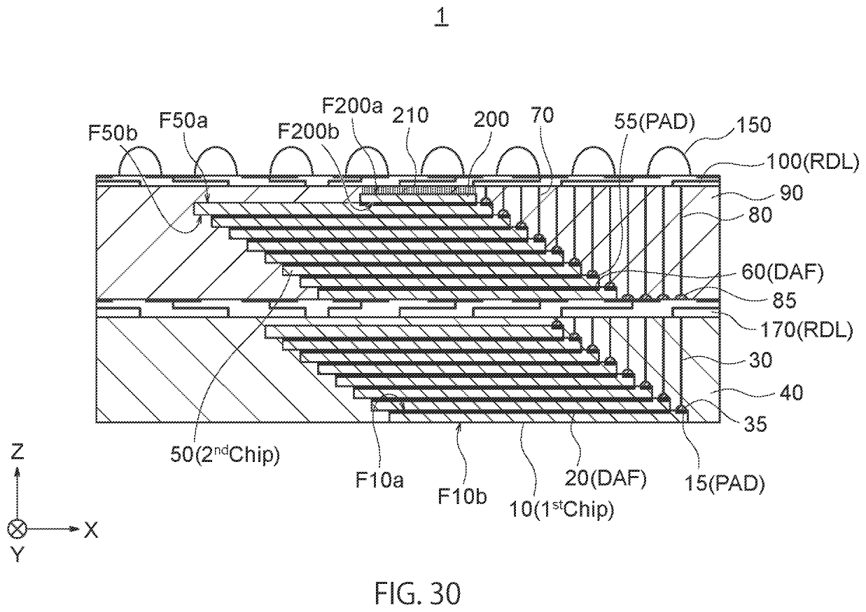

Furthermore, with the redistribution layer 170 provided between the resin layer 40 and the resin layer 90 as illustrated in FIG. 30, the pitch between the columnar electrodes 30 may be changed and be connected to the columnar electrodes 80, respectively. That is, the pitch between the columnar electrodes 80 can be different from the pitch between the columnar electrodes 30 as viewed from the Z direction. Accordingly, the semiconductor chips 50 can be stacked above the columnar electrodes 30. That is, the semiconductor chips 50 can be provided to overlap with the columnar electrodes 30 as viewed from the Z direction. As a result, the package size of the semiconductor device 1 can be reduced.

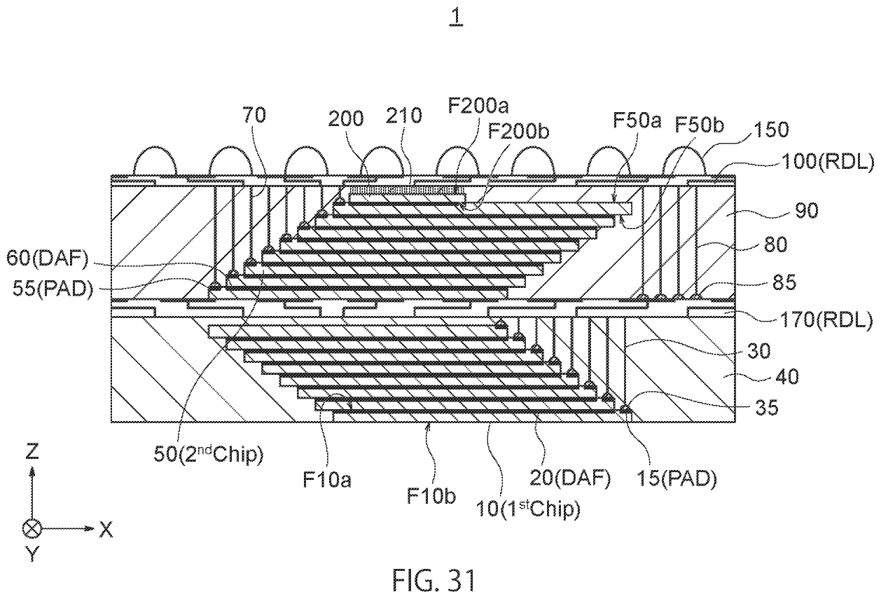

The arrangement locations of the electrode pads 55 of the semiconductor chips 50 may be on the opposite side to the arrangement locations of the electrode pads 15 of the semiconductor chips 10 as illustrated in FIG. 31. In this case, the displacement direction (the X direction) of the stacked semiconductor chips 50 is the opposite direction to the displacement direction (an −X direction) of the stacked semiconductor chips 10. This reduces the package size of the semiconductor device 1 and warp of the package of the semiconductor device 1 can be decreased.

Other configurations of the ninth embodiment may be identical to corresponding ones of the first embodiment. Therefore, the ninth embodiment can also achieve effects of the first embodiment.

### Tenth Embodiment

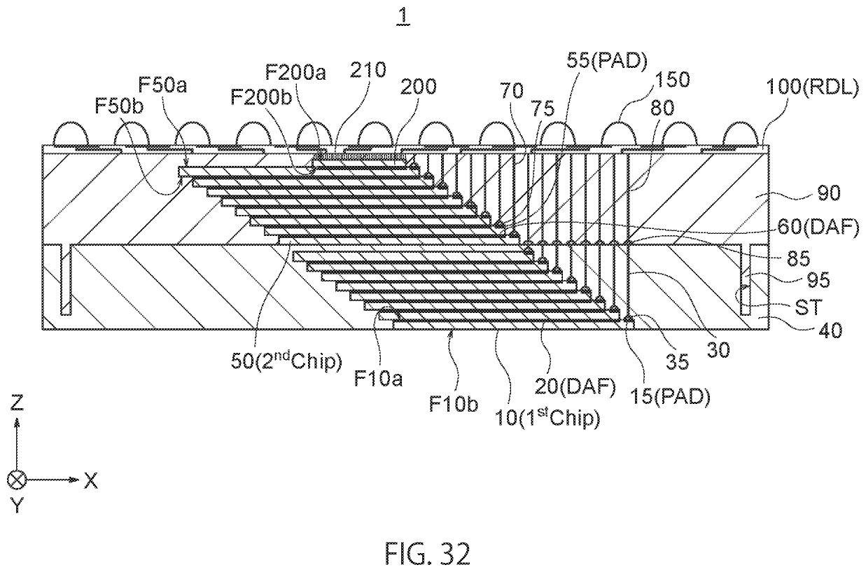

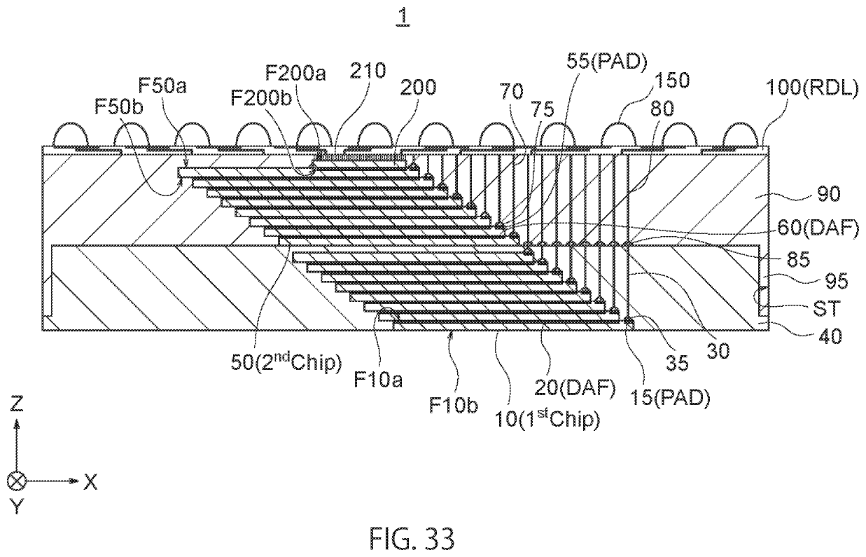

FIGS. 32 and 33 are sectional views illustrating a configuration example of the semiconductor device 1 according to a tenth embodiment. In the semiconductor device 1 according to the tenth embodiment, slits ST are provided in the resin layer 40 on both sides of the stacked layers of the semiconductor chips 10, respectively, and a resin layer 95 is embedded in the slits ST. The slits ST extend in the Y direction. In FIG. 33, portions of the slits ST are diced, whereby a form where the resin layer 95 is exposed on the side surfaces is obtained. The slits ST may be provided on four sides of the semiconductor chips 10 so as to enclose the periphery of the stacked semiconductor chips 10 as viewed from the Z direction.

The resin layer 95 can be formed of a same material as that of the resin layer 90 and be formed integrally therewith. In this case, after formation of the resin layer 40, the resin layers 90 and 95 can be formed at the same time by forming the slits ST using a lithography technique and an etching technique or a cutting technique with a blade, such as dicing, and depositing the material of the resin layer 90. Warp can also be suppressed, for example, by setting the value of “elastic modulus×thermal expansion coefficient” of the resin layers 90 and 95 as the upper layer to be smaller than the value of “elastic modulus×thermal expansion coefficient” of the resin layer 40.

The slits ST can suppress the warp of each package of the semiconductor device 1. The adhesion between the resin layer 40 and the resin layer 90 can be enhanced with the resin layer 95 in the slits ST.

Other configurations of the tenth embodiment may be identical to corresponding ones of the first embodiment. Therefore, the tenth embodiment can also achieve effects of the first embodiment. Further, the tenth embodiment may be combined with the second embodiment.

### Eleventh Embodiment

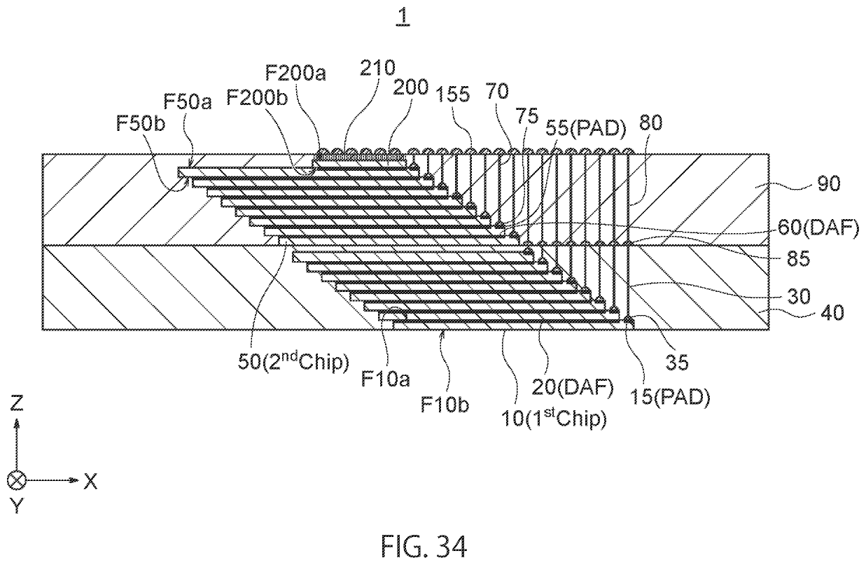

FIGS. 34 to 39 are sectional views respectively illustrating configuration examples of the semiconductor device 1 according to an eleventh embodiment. The semiconductor device 1 according to the eleventh embodiment does not include the redistribution layer 100 and further includes metallic bumps 155 on the upper ends of the columnar electrodes 70 and the columnar electrodes 210. The material of the metallic bumps 155 may be identical to that of the metallic bumps 150. That is, a conductive metal such as a simple substance of Sn, Ag, Cu, Au, Pd, Bi, Zn, Ni, Sb, In, or Ge, or a composite membrane or an alloy of two or more thereof is used as the metallic bumps 155.

When the distance between adjacent ones of the columnar electrodes 70 and the distance between adjacent ones of the columnar electrodes 210 are relatively large, the redistribution layer 100 is unnecessary and it suffices to form the metallic bumps 155 directly on the upper ends (exposed surfaces) of the columnar electrodes 70 and 210. This eliminates the process of mounting the redistribution layer 100. Since the redistribution layer 100 is not required, the cost of the semiconductor device 1 is reduced.

Electrode pads (not illustrated) may be formed on the upper ends of the columnar electrodes 70 and 210 to form the metallic bumps 155 on the electrode pads, respectively.

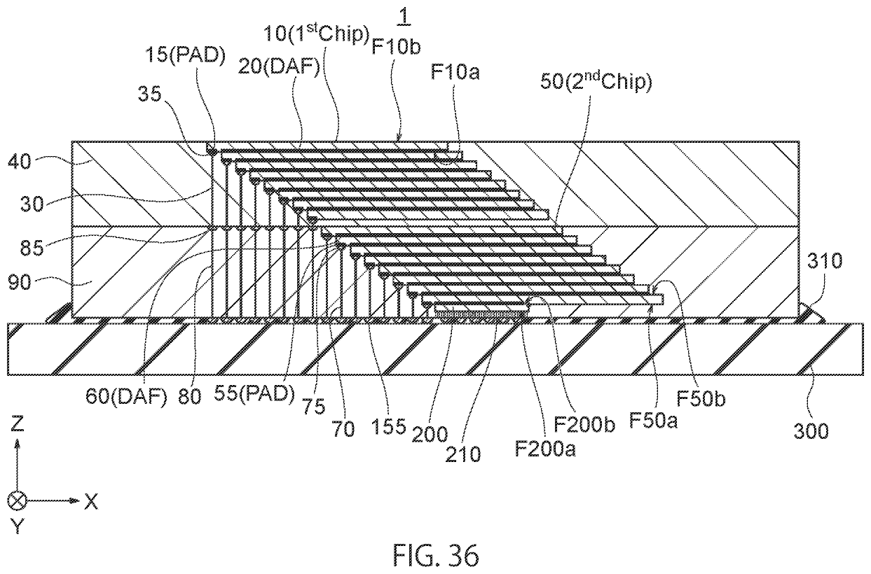

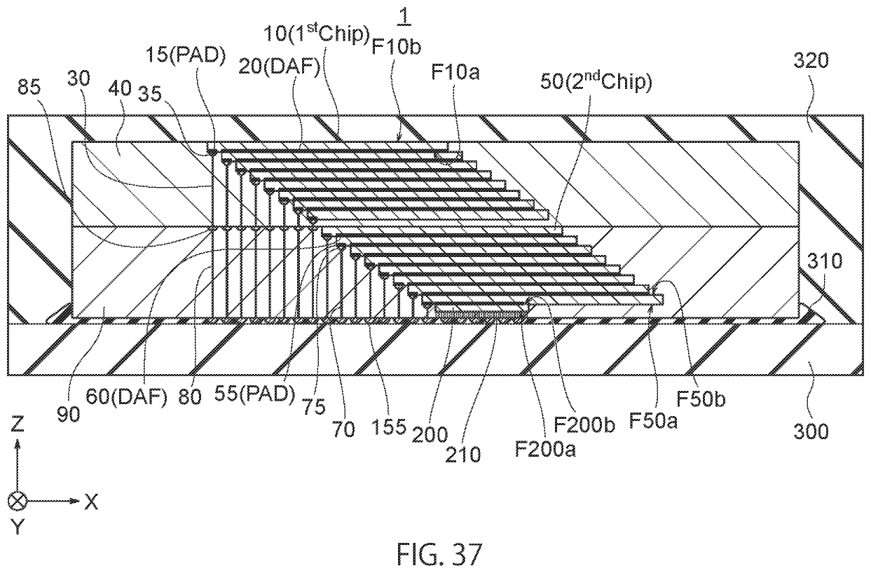

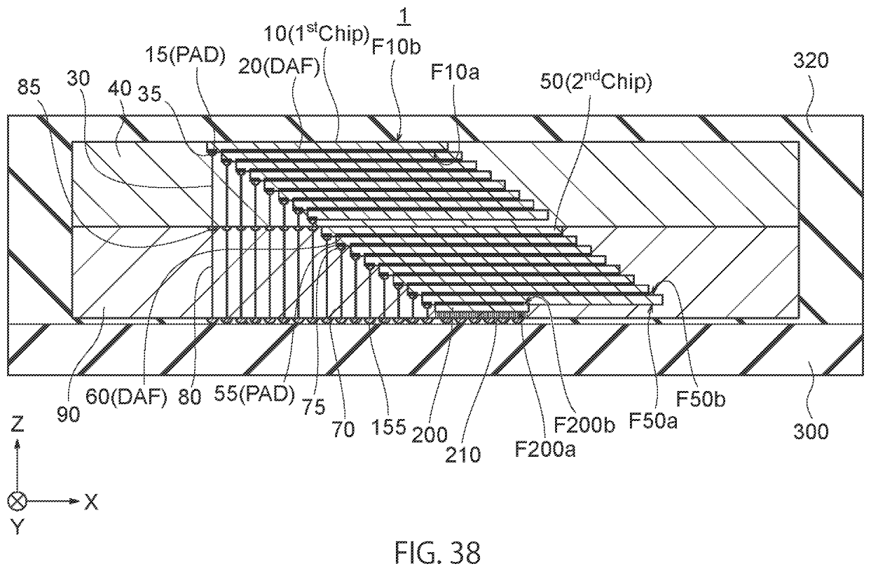

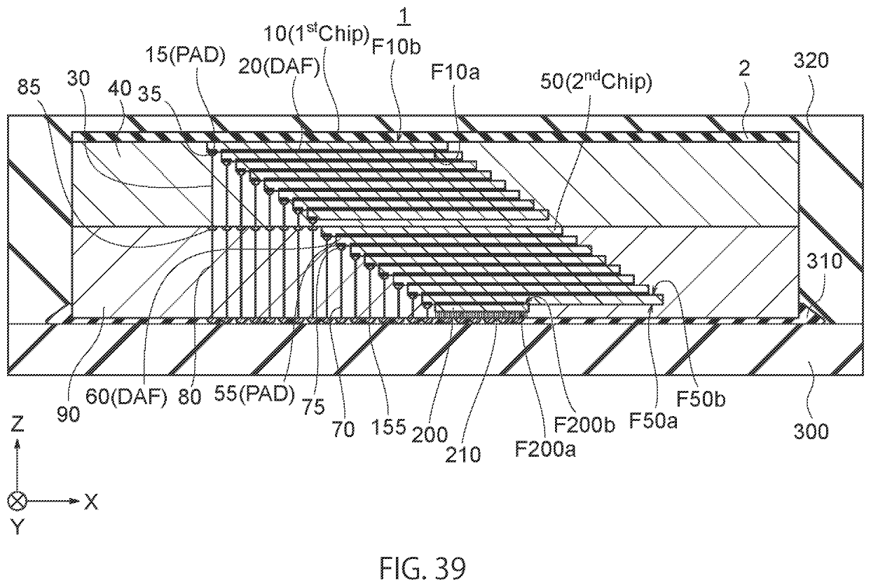

The resin body described above may be mounted on a wiring substrate 300 and a space between the resin body and the wiring substrate 300 may be sealed with a resin layer 310 as illustrated in FIG. 36. The resin body may be mounted on the wiring substrate 300, the space between the resin body and the wiring substrate 300 may be sealed with the resin layer 310, and the resultant body may be further covered with a resin layer 320 as illustrated in FIG. 37. The resin body may be mounted on the wiring substrate 300, and the space between the resin body and the wiring substrate 300 and the resin body may be entirely covered with the resin layer 320 as illustrated in FIG. 38. Alternatively, a support body 2 may be formed as illustrated in FIG. 39. The resin layers 310 and 320 can be based on a same material as that of the resin layer 40. The metallic bumps 155 may be formed on pads of the wiring substrate 300.

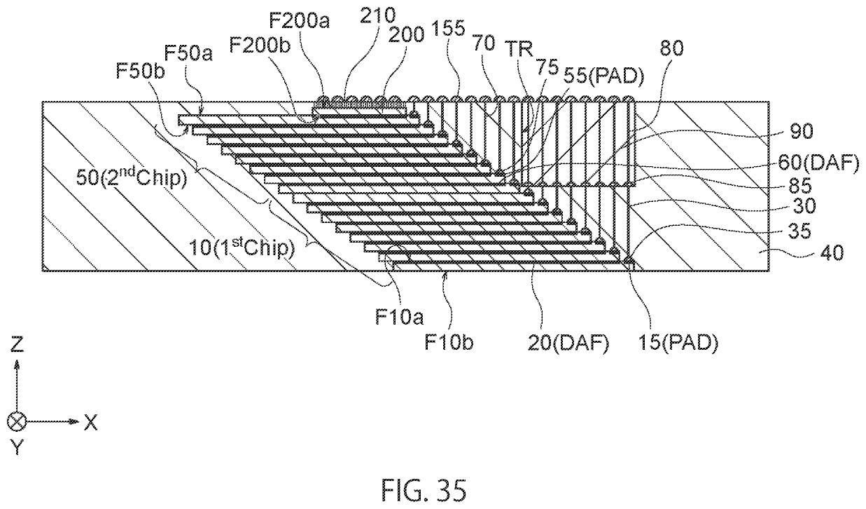

Other configurations of the eleventh embodiment may be identical to corresponding ones of the first embodiment. Therefore, the eleventh embodiment can also achieve effects of the first embodiment. Further, as illustrated in FIG. 35, the eleventh embodiment may be combined with the second embodiment.

### Twelfth Embodiment

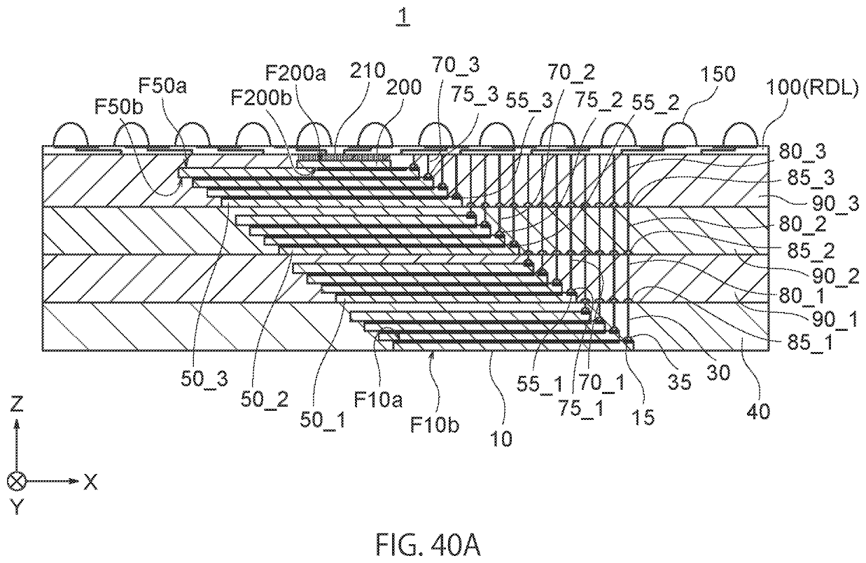

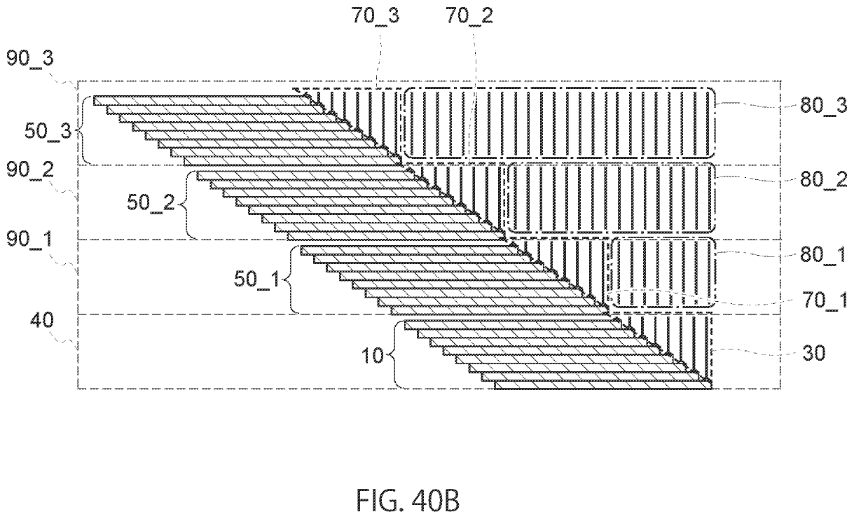

FIG. 40A is a sectional view illustrating a configuration example of the semiconductor device 1 according to a twelfth embodiment. According to the twelfth embodiment, the semiconductor chips 10 and 50 are divided into four groups of semiconductor chips 10, 50_1, 50_2, and 50_3 and are stacked to be displaced in the X direction.

The stacked semiconductor chips 10 are covered with the resin layer 40. The columnar electrodes 30 are connected to the electrode pads 15 of the semiconductor chips 10 via the connection parts 35 and extend in the Z direction. The upper ends of the columnar electrodes 30 are exposed from the resin layer 40.

The semiconductor chips 50_1 are stacked on the resin layer 40. The stacked semiconductor chips 50_1 are covered with a resin layer 90_1. Columnar electrodes 70_1 are connected to electrode pads 55_1 of the semiconductor chips 50_1 via connection parts 75_1 and extend in the Z direction. Columnar electrodes 80_1 are connected to the upper ends of the columnar electrodes 30 exposed from the resin layer 40 via connection parts 85_1, respectively, and extend in the Z direction. The resin layer 90_1 covers the semiconductor chips 50_1 and the columnar electrodes 70_1 and 80_1 and exposes the tops of the columnar electrodes 70_1 and 80_1.

The semiconductor chips 50_2 are stacked on the resin layer 90_1. The stacked semiconductor chips 50_2 are covered with a resin layer 90_2. Columnar electrodes 70_2 are connected to electrode pads 55_2 of the semiconductor chips 50_2 via connection parts 75_2 and extend in the Z direction. Columnar electrodes 80_2 are connected to the upper ends of the columnar electrodes 80_1 exposed from the resin layer 90_1 via connection parts 85_2, respectively, and extend in the Z direction. The resin layer 90_2 covers the semiconductor chips 50_2 and the columnar electrodes 70_2 and 80_2 and exposes the tops of the columnar electrodes 70_2 and 80_2.

The semiconductor chips 50_3 are stacked on the resin layer 90_2. The semiconductor chips 200 are stacked on the uppermost one of the semiconductor chips 50_3. The stacked semiconductor chips 50_3 and semiconductor chip 200 are covered with a resin layer 90_3. Columnar electrodes 70_3 are connected to electrode pads 55_3 of the semiconductor chips 50_3 via connection parts 75_3 and extend in the Z direction. Columnar electrodes 80_3 are connected to the upper ends of the columnar electrodes 80_2 exposed from the resin layer 90_2 via connection parts 85_3, respectively, and extend in the Z direction. The resin layer 90_3 covers the semiconductor chips 50_3 and the columnar electrodes 70_3 and 80_3 and exposes the tops of the columnar electrodes 70_3 and 80_3.

The redistribution layer 100 is provided on the resin layer 90_3 and is electrically connected to the columnar electrodes 70_3, 80_3, and 210. The redistribution layer 100 is a multi-layer wiring layer including a plurality of wiring layers and a plurality of insulating layers stacked and electrically connects the columnar electrodes 70_3, 80_3, and 210 to the metallic bumps 150 in terms of electrodes, respectively.

The stacked bodies of the semiconductor chips 10 and 50_1 to 50_3 can be stacked as four semiconductor packages as in the twelfth embodiment. The number of stacked semiconductor packages is not limited to four, and may be three or less, or five or more.

FIG. 40B is a schematic sectional view illustrating the semiconductor chips, the columnar electrodes, and the resin layers in FIG. 40A in an extracted manner. The twelfth embodiment is further explained with reference to FIG. 40B. A case in which the number of semiconductor packages is two is explained. The semiconductor device 1 includes a plurality of first semiconductor chips 10, and a plurality of first columnar electrodes 30 connected to electrode pads of the semiconductor chips 10 and extending in the stacking direction. The semiconductor device 1 further includes a first resin layer 40 covering the first semiconductor chips 10 and the first columnar electrodes 30 and exposing the upper ends of the first columnar electrodes 30. The semiconductor device 1 further includes a plurality of second semiconductor chips 50_1 stacked on the first semiconductor chips 10, a plurality of second columnar electrodes 70_1 connected to the electrode pads 55_1 of the second semiconductor chips 50_1 and extending in the stacking direction of the second semiconductor chips 50_1, a plurality of third columnar electrodes 80_1 respectively connected to the first columnar electrodes 30, and a second resin layer 90_1 covering the second semiconductor chips 50_1, the second columnar electrodes 70_1, and the third columnar electrodes 80_1 and exposing the upper ends of the second columnar electrodes 70_1 and the third columnar electrodes 80_1.

A case in which the number of semiconductor packages is three is further explained. It is assumed here that a natural number k is set to 3 or is incremented from 3 to any natural number n (n>=4). The case in which the number of stacked bodies is three corresponds to a case in which k=3 is established. At this time, a plurality of kth semiconductor chips (third semiconductor chips 50_2) stacked on a plurality of (k−1)th semiconductor chips (that is, the second semiconductor chips 50_1), a plurality of (2k−2)th columnar electrodes (fourth columnar electrodes 70_2) connected to electrode pads 55_2 of the kth semiconductor chips 50_2 and extending in the stacking direction of the kth semiconductor chips 50_2, a plurality of (2k−1)th columnar electrodes (fifth columnar electrodes 80_2) respectively connected to a plurality of (2k−4)th columnar electrodes (the second columnar electrodes 70_1) and a plurality of (2k−3)th columnar electrodes (the third columnar electrodes 80_1), and a kth resin layer (a third resin layer 90_2) covering the kth semiconductor chips 50_2, the (2k−2)th columnar electrodes 70_2, and the (2k−1)th columnar electrodes 80_2 and exposing the upper ends of the (2k−2)th columnar electrodes 70_2 and the (2k−1)th columnar electrodes 80_2 are further included in the case in which the number of stacked bodies is two.

When the number of semiconductor packages is increased to four, five, or a still larger value, cases in which k is incremented by one, that is, k=4, 5, and a larger value are also added to the case in which k=3 is established. In this way, even when the number of semiconductor packages is increased to any number, these cases are explainable using the value of the natural number k.

The redistribution layer 100 is provided on the kth resin layer (k=3 or n) and is electrically connected to the (2k−2)th columnar electrodes, the (2k−1)th columnar electrodes, and the columnar electrodes 210. The redistribution layer 100 is a multi-layer wiring layer including a plurality of wiring layers and a plurality of insulating layer stacked and connects the (2k−2)th columnar electrodes, the (2k−1)th columnar electrodes, and the columnar electrodes 210 to the metallic bumps 150 in terms of electrodes, respectively.

Materials of the first resin layer 40, the second resin layer 90_1, and the subsequent kth resin layer (k=3 or n) can be same or different from each other. By causing the materials of the first resin layer 40, the second resin layer 90_1, and the subsequent kth resin layer (k=3 or n) to be different from each other, entire warp of the semiconductor packages can be suppressed. The upper ends of the columnar electrodes are not necessarily exposed from the first, second, or kth resin layer (k>=3) and it suffices that at least some portions thereof are exposed in any way.

### Thirteenth Embodiment

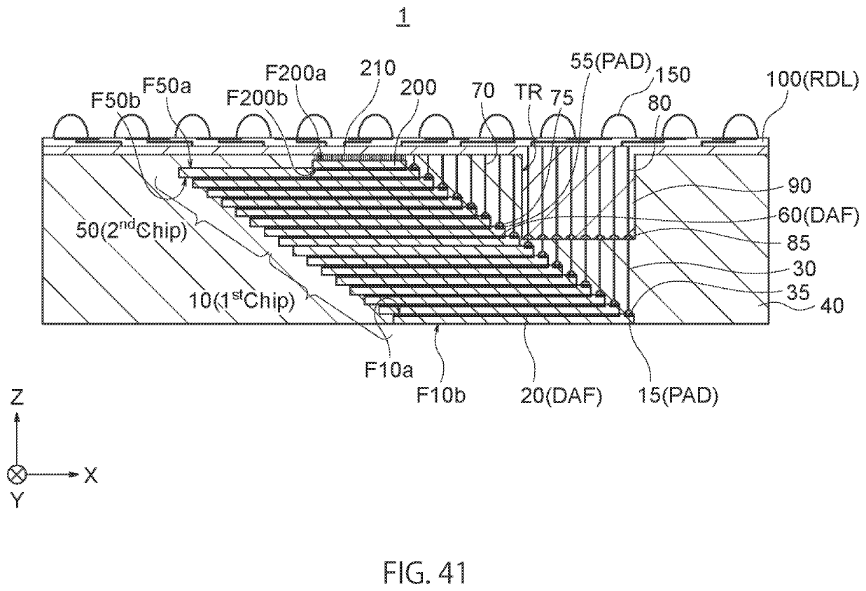

FIG. 41 is a sectional view illustrating a configuration example of the semiconductor device 1 according to a thirteenth embodiment. According to the thirteenth embodiment, the resin layer 90 is provided also between the resin layer 40 and the redistribution layer 100 as well as in the trenches TR. Other configurations of the thirteenth embodiment may be identical to corresponding configurations of the second embodiment.

By setting the stress of the resin layer 40 and the stress of the resin layer 90 to be opposite to each other, warp of each package of the semiconductor device 1 can be adjusted and the reliability can be improved.

### Fourteenth Embodiment

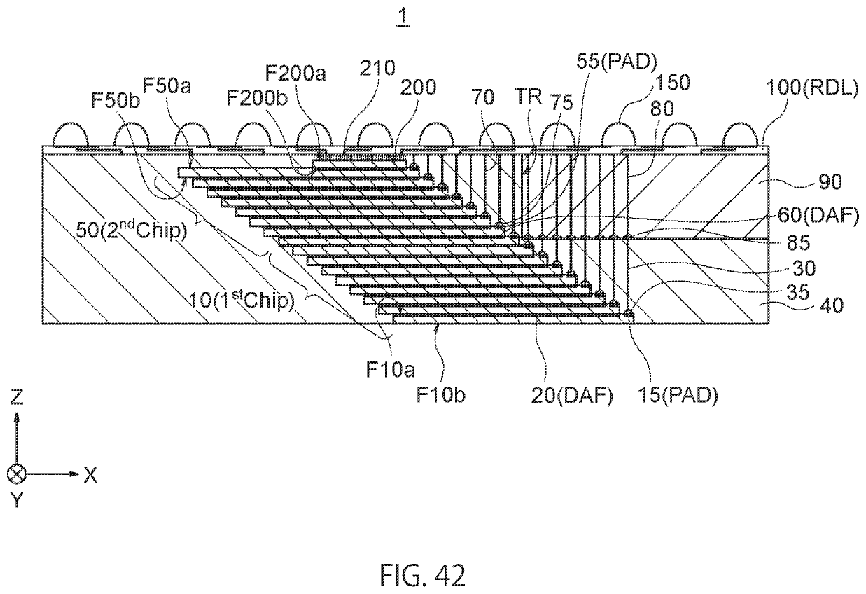

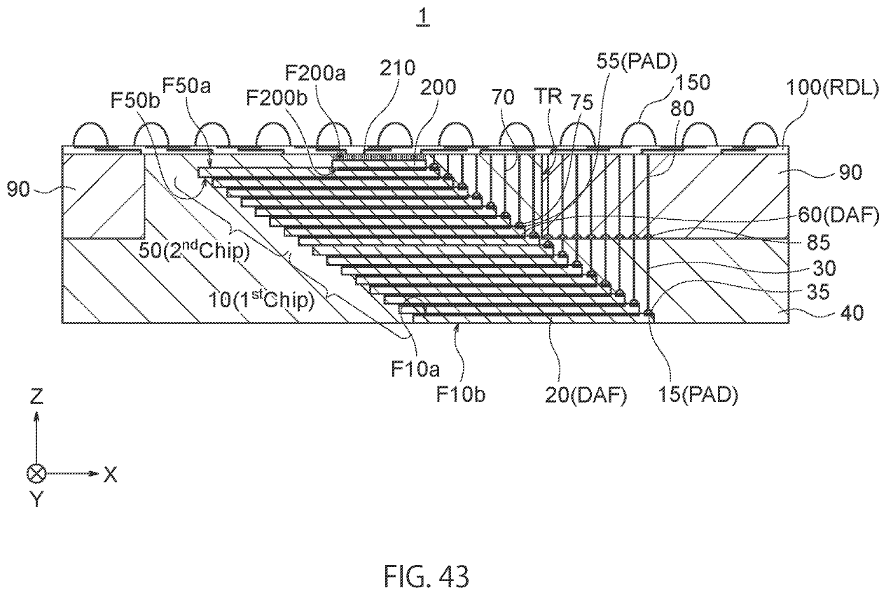

FIGS. 42 and 43 are sectional views respectively illustrating configuration examples of the semiconductor device 1 according to a fourteenth embodiment. According to the fourteenth embodiment, the trenches TR are provided to the side surface of at least one end of each package of the semiconductor device 1 and expose the tops of the columnar electrodes 30 on the bottom portions. With this arrangement, the resin layer 90 is provided to this end of each package of the semiconductor device 1. Therefore, the resin layer 90 is present also on the side surface of each package of the semiconductor device 1. While the resin layer 40 is present on the side surface of each package, the resin layer 90 is present on the upper part of the resin layer 40.

The resin layer 90 is provided only on one end of each package of the semiconductor device 1 in FIG. 42. The resin layer 90 is provided on both ends of each package of the semiconductor device 1 in FIG. 43. Other configurations of the fourteenth embodiment may be identical to corresponding configurations of the second embodiment.

The width of the trenches TR can be widened by widening the polishing width at the time of polishing the resin layer 40. The trenches TR and the resin layer 90 can be provided on both sides of each package by polishing the resin layer 40 on the both sides of the package.

Warp of each package of the semiconductor device 1 can be adjusted by setting the stress of the resin layer 40 and the stress of the resin layer 90 to be opposite to each other and adjusting the volume of the resin layer 90. Accordingly, the reliability of the semiconductor device 1 can be improved. Other configurations of the fourteenth embodiment may be identical to corresponding configurations of the second embodiment.

### Fifteenth Embodiment

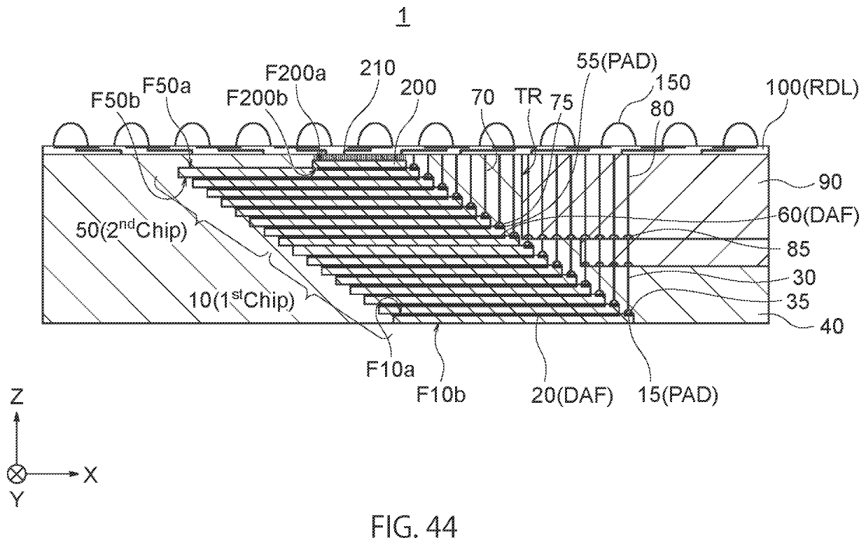

FIG. 44 is a sectional view illustrating a configuration example of the semiconductor device 1 according to a fifteenth embodiment. According to the fifteenth embodiment, the trenches TR are formed in a stepwise manner in the resin layer 40. With this arrangement, the resin layer 90 embedded in the trenches TR is also provided in a stepwise manner in the trenches TR. The semiconductor device 1 according to the present embodiment can be formed by repeating formation of the trenches TR, formation of the columnar electrodes 80, and embedment of the resin layer 90. Since this enables the columnar electrodes 30 and 80 to be formed while being spliced, long columnar electrodes 30 and 80 can be formed in a substantially linear manner in the vertical direction. As a result, the reliability of the semiconductor device 1 is enhanced.

Other configurations of the fifteenth embodiment may be identical to corresponding ones of the fourteenth embodiment. Therefore, the fifteenth embodiment can also achieve effects of the fourteenth embodiment.

### Sixteenth Embodiment

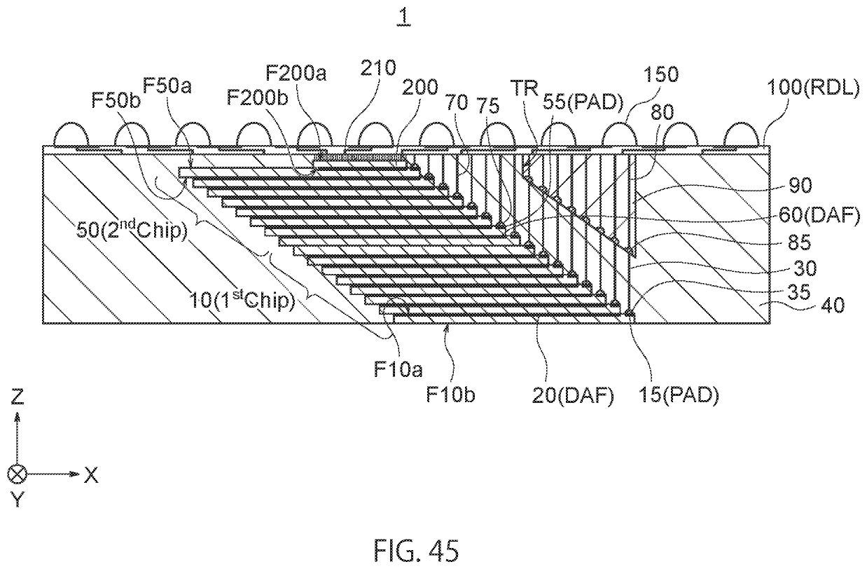

FIG. 45 is a sectional view illustrating a configuration example of the semiconductor device 1 according to a sixteenth embodiment. According to the sixteenth embodiment, bottom surfaces of the trenches TR and the resin layer 90 are inclined with respect to the X-Y plane (the faces F10a and F10b). The bottom surfaces of the trenches TR and the resin layer 90 are preferably inclined in a substantially parallel to displacement of the side surfaces of the stacked body of the semiconductor chips 10 and 50 (the inclination of the side surfaces of the stacked body). That is, the semiconductor chips 10 and 50 are stacked to be displaced in a certain inclination direction with respect to the faces F10a, F10b, F50a, and F50b. The bottom surfaces of the trenches TR are inclined along the inclination direction of stacking of the semiconductor chips 10 and 50. Accordingly, the lengths of the columnar electrodes 30 can be formed to be substantially equal and bend or collapse of the columnar electrodes 30 can be suppressed. Furthermore, the volume of the resin layer 90 can be formed relatively small. Warp of each package can be reduced as the volume of the resin layer 90 is smaller in some cases. In these cases, the reliability of the semiconductor device 1 can be improved by decreasing the volume of the resin layer 90 as in the sixteenth embodiment. Other configurations of the sixteenth embodiment may be identical to corresponding ones of the second embodiment. Therefore, the sixteenth embodiment can also achieve effects of the second embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a plurality of stacked first semiconductor chips;
first columnar electrodes connected to electrode pads of the first semiconductor chips and extending in a stacking direction of the first semiconductor chips;
a plurality of second semiconductor chips stacked above the first semiconductor chips;
second columnar electrodes connected to electrode pads of the second semiconductor chips and extending in a stacking direction of the second semiconductor chips;
third columnar electrodes respectively connected to tops of the first columnar electrodes and extending in the stacking direction of the second semiconductor chips; and
a resin layer covering the first semiconductor chips, the second semiconductor chips, the second columnar electrodes, and the third columnar electrodes and exposing tops of the second and third columnar electrodes.

2. The device of claim 1, wherein
the resin layer comprises
a first resin layer covering the first semiconductor chips and the first columnar electrodes and exposing the tops of the first columnar electrodes, and
a second resin layer covering the second semiconductor chips, the second columnar electrodes, and the third columnar electrodes and exposing the tops of the second and third columnar electrodes, and
the third columnar electrodes are respectively connected to the tops of the first columnar electrodes exposed from the first resin layer and extend in the stacking direction of the second semiconductor chips.

3. The device of claim 1, wherein
the resin layer comprises
a first resin layer covering the first semiconductor chips, the second semiconductor chips, and the first and second columnar electrodes, the first resin layer exposing the tops of the second columnar electrodes on an upper surface of the first resin layer and exposing tops of the first columnar electrodes on a bottom portion of a trench or a tier provided in the first resin, and
a second resin layer provided in the trench or the tier,
the third columnar electrodes are connected to the tops of the first columnar electrodes exposed in the trench or the tier in the first resin layer and extend in the stacking direction of the second semiconductor chips, and
the second resin layer covers the third columnar electrodes and exposes the tops of the third columnar electrodes.

4. The device of claim 3, wherein the trench extends in a substantially parallel direction to a side of the first or second semiconductor chips on which the electrode pads are provided.

5. The device of claim 2, wherein the first resin layer is interposed between an uppermost tier of the first semiconductor chips and a lowermost tier of the second semiconductor chips.

6. The device of claim 1, further comprising connection parts each having a larger size of a cross section in a perpendicular direction to an extending direction of the third columnar electrodes than those of the first and third columnar electrodes between the first columnar electrodes and the third columnar electrodes.

7. The device of claim 1, further comprising:
a wiring layer provided on the resin layer and electrically connected to the third columnar electrodes; and
a bump provided on the wiring layer and electrically connected to the wiring layer.

8. The device of claim 1, wherein a size of a cross section in a perpendicular direction to an extending direction of the third columnar electrodes differs between the third columnar electrodes and the first and second columnar electrodes.

9. The device of claim 1, wherein a material of the third columnar electrodes is different from those of the first and second columnar electrodes.

10. The device of claim 1, further comprising additional pads provided on top portions of the first columnar electrodes exposed from the resin layer and having a larger area than an exposed area of the top portions of the first columnar electrodes, respectively.

11. The device of claim 1, wherein a plurality of the third columnar electrodes are connected to correspond to a certain one of the first columnar electrodes.

12. The device of claim 2, wherein different materials are used for the first resin layer and the second resin layer, respectively.

13. The device of claim 2, further comprising a third resin layer between the first resin layer and the second resin layer.

14. The device of claim 2, further comprising a second wiring layer between the first resin layer and the second resin layer, wherein
top end portions of the first columnar electrodes are electrically connected to a first face of the second wiring layer,
lower end portions of the third columnar electrodes are electrically connected to a second face of the second wiring layer on an opposite side to the first face, and
the second wiring layer electrically connects the first columnar electrodes and the third columnar electrodes to each other.

15. The device of claim 14, wherein the third columnar electrodes are arranged at different locations from those of the first columnar electrodes as viewed from a stacking direction of the first and second semiconductor chips.

16. The device of claim 14, wherein each pitch of a plurality of the third columnar electrodes is different from that of a plurality of the first columnar electrodes as viewed from a stacking direction of the first and second semiconductor chips.

17. The device of claim 2, wherein the second resin layer is filled in a slit provided in the first resin layer.

18. A semiconductor device comprising:
a plurality of stacked first semiconductor chips, a plurality of first columnar electrodes connected to electrode pads of the first semiconductor chips and extending in a stacking direction of the first semiconductor chips, and a first resin layer covering the first semiconductor chips and the first columnar electrodes and exposing portions of the first columnar electrodes;
a plurality of second semiconductor chips stacked on the first semiconductor chips, a plurality of second columnar electrodes connected to electrode pads of the second semiconductor chips and extending in a stacking direction of the second semiconductor chips, a plurality of third columnar electrodes respectively connected to the first columnar electrodes, and a second resin layer covering the second semiconductor chips, the second columnar electrodes, and the third columnar electrodes and exposing portions of the second columnar electrodes and the third columnar electrodes; and
a plurality of kth semiconductor chips stacked on the (k−1)th semiconductor chips, a plurality of (2k−2)th columnar electrodes connected to electrode pads of the kth semiconductor chips and extending in a stacking direction of the kth semiconductor chips, a plurality of (2k−1)th columnar electrodes respectively connected to the (2k−4)th columnar electrodes and the (2k−3)th columnar electrodes, and a kth resin layer covering the kth semiconductor chips, the (2k−2)th columnar electrodes, and the (2k−1)th columnar electrodes and exposing portions of the (2k−2)th columnar electrodes and the (2k−1)th columnar electrodes,
where a natural number k meets k=3 or is incremented by one from k=3 to any natural number n (n>=4).

19. The device of claim 1, further comprising another semiconductor chip on the second semiconductor chips or kth semiconductor chips.

20. The device of claim 3, wherein the trench is provided to a side surface of the first resin layer and exposes tops of the first columnar electrodes on a bottom portion.
